(19) United States
(12) Patent Application Publication
(10) Pub. No.: US 2007/0222043 A1
(43) Pub. Date: Sep. 27, 2007

(54) Semiconductor device and a method of manufacturing the same

(75) Inventors: Kozo Watanabe, Tokyo (JP); Michimoto Kaminaga, Tokyo (JP); Katsuhiko Hotta, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/705,052

(22) Filed: Feb. 12, 2007

(30) Foreign Application Priority Data
Mar. 27, 2006 (JP) 2006-85755

(51) Int. Cl. H01L 23/495

(52) U.S. Cl. 257/666

(57) ABSTRACT

A technique is provided for improving the security of information stored in a semiconductor device. Multilayer wiring layers are formed over a semiconductor substrate. Wirings are formed on the uppermost wiring layer among those multilayer wiring layers. On the wirings, there is formed, in the following order, a silicon oxide film, a colored thin film, and a silicon oxide film, over which, a silicon nitride film serving as a surface protective film is formed. In other words, the invention is characterized by that the colored thin film is formed between the wiring constituting the uppermost wiring layer and the silicon nitride film serving as the surface protective film. The colored thin film has a function of attenuating visible light and laser light in the specific wavelength region, and is formed of, for example, a silicon oxide film containing cobalt oxide.

### CROSS-REFERENCE TO RELATED APPLICATION

The present application claims priority from Japanese patent application No. 2006-85755 filed on Mar. 27, 2006, the content of which is hereby incorporated by reference into this application.

### BACKGROUND OF THE INVENTION

The present invention relates to a semiconductor device and a technique for manufacturing the same, and more particularly, to a technique effectively applied to a semiconductor device requiring security, such as an IC (Integrated Circuit) card, and manufacture of the same.

WO03/015169 discloses a technique for improving the security of information stored in the semiconductor device. More specifically, a wiring for supplying a power source voltage to supply a driving voltage to an integrated circuit in a semiconductor chip is so formed as to cover a main surface of the semiconductor chip. If the wiring is removed so as to analyze the information stored in the chip, the integrated circuit will not become operative to prevent the information analysis. A process detecting circuit is further provided for detecting process of the wiring. When the process detecting circuit detects process of the wiring, the integrated circuit is adapted to be reset.

Japanese Unexamined Patent Publication No. 2000-183291 discloses a semiconductor device which makes it difficult to analyze a circuit structure to prevent unauthorized-copying or imitation of the circuit structure or falsification of the information by others. More specifically, a lamination of a strained aluminum oxide film and a conductive metal film that hardly transmits light is provided on a protective film formed on the circuit structure of a semiconductor chip.

### SUMMARY OF THE INVENTION

In an IC card (semiconductor device), reading and writing of data from and to a memory is managed by the function of a CPU (Central Processing Unit) incorporated therein. The IC card has itself a high security function of performing encryption processing. Since it has a larger storage capacity than a magnetic card, the IC card has been considered to be used as an information storage medium in fields including finance, distribution, medical services, traffic, transportation, and education.

The IC card normally has a recess formed in a part of a plastic film of substantially the same size as a business card, and a semiconductor chip packaged is embedded into the recess. Elements including a multilayer wiring, a MISFET, and the like are formed in the semiconductor chip, and a surface protective film is formed on the uppermost layer of the chip. The thus-constructed IC card is required to have the high security feature. For this reason, it is important to render information on the layout of the multilayer wiring formed inside the semiconductor chip invisible, and thus to make it difficult to analyze the integrated circuit formed inside the semiconductor chip.

Techniques for improving the security of the information stored in the semiconductor device, such as the IC card, include one which involves forming security shield patterns with wiring layers formed in the semiconductor chip so as to provide the security of the information. For example, the technique involves forming dummy patterns or wirings embedded in free spaces between the wirings, thereby making it difficult to read the layout information about the multilayer wiring. Furthermore, another technique involves forming a relatively large solid pattern covering one functional module, such as a mask ROM (Read Only Memory), a Logic circuit, or a SRAM (Static Random Access Memory), of the semiconductor chip, thereby rendering the functional module present under the solid pattern less identifiable. Moreover, the so-called active shield technique is proposed which involves laying wiring patterns formed adjacent to a power source wiring and a GND wiring, and forcefully resetting the integrated circuit formed in or on the semiconductor chip when either an open or a short is electrically detected.

On the other hand, in recent years, the IC card is required to have resistance to measures that may cause the IC card to malfunction by irradiating the semiconductor chip with light and feeding current through a pn junction or the like formed in the semiconductor chip. To cope with this problem, a technique is proposed which involves embedding in the chip a light detector which is designed to detect the light by the pn junction or the like, and to forcefully reset an integrated circuit formed in the semiconductor chip. Another technique is also proposed which involves providing a light non-transparent material on the surface protective film (passivation film) formed on the uppermost layer of the semiconductor chip.

The above-mentioned technique for forming the solid pattern covering the functional module has a high effect of cutting off the light, such as laser light or flashlight, but has a problem that the solid pattern can be removed relatively easily by a physical method, such as a FIB (Focused Ion Beam).

In contrast, the active shield technique is designed to detect the open or short to reset the integrated circuit when the wiring pattern is intended to be removed by the physical method. The active shield technique has high resistance to physical attack. However, since the light is transmitted through the space between the wirings, the active shield technique has a problem that it has a susceptibility to the attack using the light. In this regard, the same goes for the technique for forming the dummy pattern.

Combination of the solid pattern forming technique and the active shield technique can obtain advantages of both. This, however, results in another problem of an increase in cost of the semiconductor device due to an increase in number of the wiring layers which are not related to the essential real wiring.

In the technique for providing the light detector in the semiconductor chip, the number of the light detectors which can be mounted in the chip is limited. If the restricted beam, such as collected light or laser light, is applied to the chip avoiding the positions of the light detectors, those detectors cannot disadvantageously detect the light. A light blocking material provided outside the surface protective film may disadvantageously be removed easily without having any influence on the semiconductor chip itself.

It is therefore an object of the invention to provide a technique for improving the security of the information stored in a semiconductor device.

The above-mentioned and other objects and novel features of the invention will be apparent from the following description with reference to the accompanying drawings.

The outline of typical features of the invention disclosed in the present application will be briefly described as follows.

A semiconductor device according to one aspect of the invention includes (a) an uppermost wiring layer formed over a semiconductor substrate, (b) an interlayer insulating film formed over the uppermost wiring layer, and (c) a surface protective film formed over the interlayer insulating film. A colored thin film for attenuating visible light and laser light in a specific wavelength region is formed in or at the interlayer insulating film.

A method of manufacturing a semiconductor device according to another aspect of the invention includes the steps of (a) forming a wiring layer over a semiconductor substrate, (b) forming an interlayer insulating film over the wiring layer, and (c) forming a surface protective film over the interlayer insulating film. The (b) step includes the step of (d) forming a colored thin film for attenuating visible light and laser light in a specific wavelength region.

The effects obtained by the typical features of the invention disclosed herein will be briefly described as follows.

Such formation of the colored thin film in the interlayer insulating film of the semiconductor chip can decrease the possibility that the circuit information in the semiconductor chip may be read out, thereby preventing the malfunction of the semiconductor device due to irradiation of the light.

### BRIEF DESCRIPTION OF THE DRAWINGS

FIG. 1 is an entire plan view showing an IC card according to a first preferred embodiment of the invention;

FIG. 2 is a sectional view taken along the line A-A of FIG. 1;

FIG. 3 is a sectional view showing a modified example of FIG. 2;

FIG. 4 is a top view showing a layout structure of respective elements formed in a semiconductor chip;

FIG. 5 is a sectional view showing a section of a semiconductor device of the first embodiment;

FIG. 6 is a sectional view showing a manufacturing step of the semiconductor device of the first embodiment;

FIG. 7 is a sectional view showing a manufacturing step of the semiconductor device, following the step of FIG. 6;

FIG. 8 is a sectional view showing a manufacturing step of the semiconductor device, following the step of FIG. 7;

FIG. 9 is a sectional view showing a manufacturing step of the semiconductor device, following the step of FIG. 8;

FIG. 10 is a sectional view showing a manufacturing step of the semiconductor device, following the step of FIG. 9;

FIG. 11 is a sectional view showing a manufacturing step of the semiconductor device, following the step of FIG. 10;

FIG. 12 is a sectional view showing a manufacturing step of the semiconductor device, following the step of FIG. 11;

FIG. 13 is a sectional view showing a manufacturing step of the semiconductor device, following the step of FIG. 12;

FIG. 14 is a sectional view showing a manufacturing step of the semiconductor device, following the step of FIG. 13;

FIG. 15 is a flowchart for explaining steps of forming a colored thin film;

FIG. 16 is a sectional view showing a manufacturing step of the semiconductor device, following the step of FIG. 14;

FIG. 17 is a sectional view showing a manufacturing step of the semiconductor device, following the step of FIG. 16;

FIG. 18 is a sectional view showing a manufacturing step of the semiconductor device, following the step of FIG. 17;

FIG. 19 is a sectional view showing a section of a semiconductor device according to a second preferred embodiment of the invention;

FIG. 20 is a sectional view showing a manufacturing step of the semiconductor device of the second embodiment;

FIG. 21 is a sectional view showing a manufacturing step of the semiconductor device, following the step of FIG. 20;

FIG. 22 is a sectional view showing a manufacturing step of the semiconductor device, following the step of FIG. 21;

FIG. 23 is a sectional view showing a manufacturing step of the semiconductor device, following the step of FIG. 22;

FIG. 24 is a sectional view showing a manufacturing step of the semiconductor device, following the step of FIG. 23;

FIG. 25 is a sectional view showing a manufacturing step of the semiconductor device, following the step of FIG. 24;

FIG. 26 is a sectional view showing a modified example of the second embodiment;

FIG. 27 is a sectional view showing another modified example of the second embodiment;

FIG. 28 is a sectional view showing a manufacturing step of a semiconductor device according to a third preferred embodiment of the invention;

FIG. 29 is a sectional view showing a manufacturing step of the semiconductor device, following the step of FIG. 28;

FIG. 30 is a sectional view showing a manufacturing step of the semiconductor device, following the step of FIG. 29;

FIG. 31 is a sectional view showing a manufacturing step of the semiconductor device, following the step of FIG. 30;

FIG. 32 is a sectional view showing a semiconductor device according to a fourth preferred embodiment of the invention;

FIG. 33 is a sectional view showing a manufacturing step of the semiconductor device of the fourth preferred embodiment;

FIG. 34 is a sectional view showing a manufacturing step of the semiconductor device, following the step of FIG. 33;

FIG. 35 is a sectional view showing a manufacturing step of the semiconductor device, following the step of FIG. 34; and

FIG. 36 is a sectional view showing a manufacturing step of the semiconductor device, following the step of FIG. 35.

### DESCRIPTION OF THE PREFERRED EMBODIMENTS

The following embodiments will be described by being divided into a plurality of sections or embodiments if necessary for convenience. However, unless otherwise specified, they are not irrelevant to one another. One of the embodiments has to do with modifications, details and supplementary explanations of some or all of the other.

When reference is made to the number of elements or the like (including the number of pieces, numerical values, quantity, range, etc.) in the following description of the embodiments, the number thereof is not limited to a specific number, and may be greater than, or less than, or equal to the specific number, unless otherwise specific and definitely limited to the specific number in principle.

It is also needless to say that components (including elements or process steps, etc.) employed in the following description of the embodiments are not always essential, unless otherwise specified and considered to be definitely essential in principle.

Similarly, when reference is made to the shapes, positional relations and the like of the components or the like in the following description of the embodiments, they will include ones substantially analogous or similar to their shapes or the like, unless otherwise specified and considered not to be definitely so in principle, etc. The same goes for the above-mentioned numeral value and range.

The same reference numbers will be used in principle to refer to the same or like parts throughout all the drawings for explanation of the embodiments, and thus the repeated description thereof will be omitted.

### First Preferred Embodiment

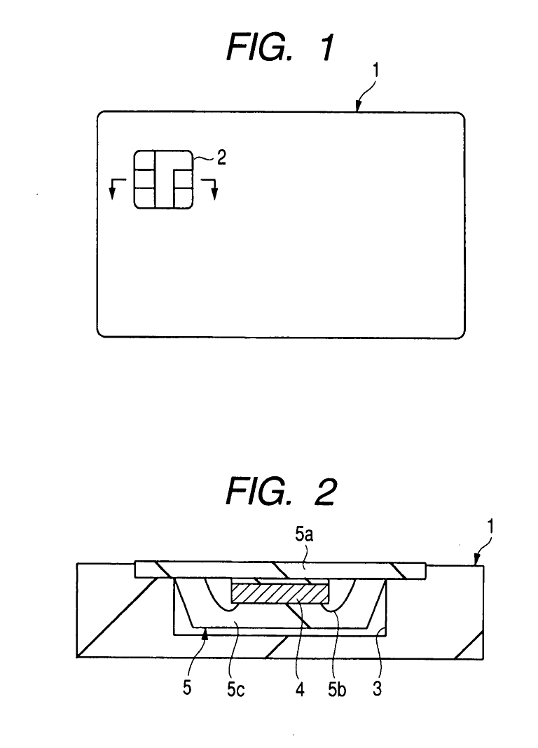

FIG. 1 is an entire plan view of an IC card (semiconductor device) 1 according to a first preferred embodiment of the invention. FIG. 2 is a sectional view taken along the line A-A of FIG. 1.

The IC card 1 is used as various kinds of information storage medium, for example, as electronic money, a credit card, a cellular phone, a pay satellite broadcast receiver, an identification card, a license, an insurance card, an electronic chart, an electronic railroad ticket, or the like, in fields including finance, distribution, medical services, traffic, transportation, and education. The IC card 1 is made of a plastic film having, for example, a rectangular planar shape. The IC card 1 is, for example, about 85.47 to 85.72 mm×53.92 to 54.03 mm in length and width, and about 0.68 to 1.84 mm in thickness.

An information storage area 2 having a substantially rectangular planar shape is provided in a part of the main surface of the IC card 1. The information storage area 2 has a groove 3 formed therein as shown in FIG. 2, and a package 5 incorporating therein a semiconductor chip 4 is embedded in the groove 3. The information storage area 2 is, for example, about 11.4×12.6 mm in length and width.

The semiconductor chip 4 is mounted on a package substrate 5a with its main surface (device forming surface) directed to the bottom of the groove 3, and with its back surface in contact with a package substrate 5a. The semiconductor chip 4 has bonding pads electrically connected to lands (electrodes) formed on the package substrate 5a via bonding wires 5b made of, for example, gold (Au). The thus-constructed semiconductor chip 4 and the bonding wires 5b are sealed by a seal resin 5c made of, for example, epoxy resin. The back surface of the package substrate 5a, that is, a surface opposite to the mounting surface of the semiconductor chip 4 is faced to the front surface side of the IC card 1. A plurality of electrodes are formed on the back surface of the package substrate 5a to be electrically connected to the lands (electrodes) formed on the front surface of the package substrate 5a (mounting surface of the semiconductor chip 4). Through these electrodes, the semiconductor chip 4 can be accessed from the outside. That is, data can be transmitted to and received from the semiconductor chip 4 embedded inside the IC card 1 via the plural electrodes formed on the surface of the IC card 1.

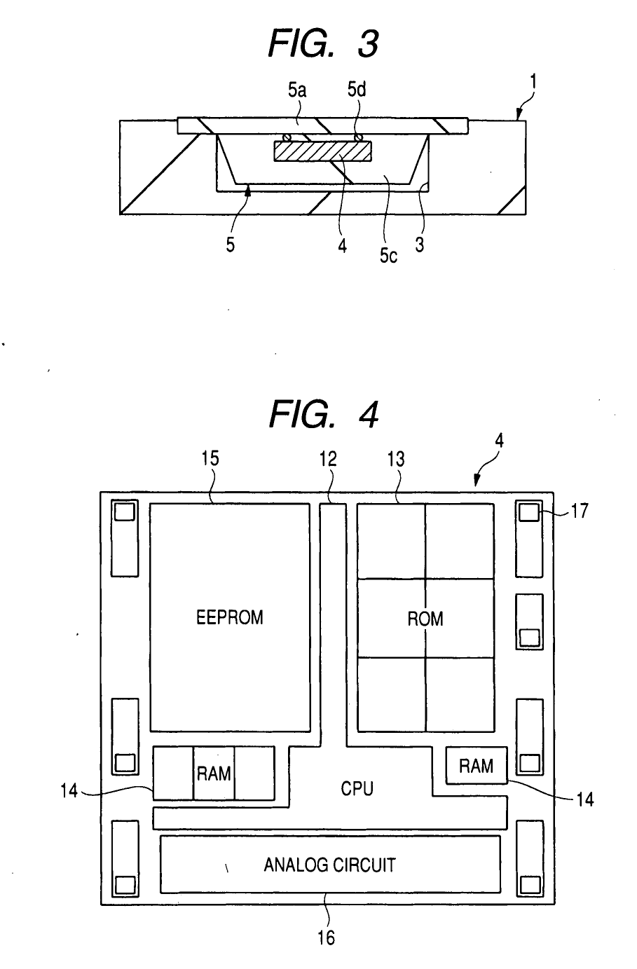

Mounting methods of the semiconductor chip 4 for use may include not only the way as shown in FIG. 2, but also a face-down bonding scheme, for example, as shown in FIG. 3. That is, the scheme may be employed in which bump electrodes 5d are formed on external terminals of the semiconductor chip 4, and the semiconductor chip 4 is mounted on the package substrate 5a with the main surface of the chip 4 directed to the package substrate 5a. The semiconductor chip 4 is electrically connected to the wirings formed on the package substrate 5a via the bump electrodes 5d.

Now, a layout structure of an integrated circuit formed in the semiconductor chip 4 will be described below. FIG. 4 shows a top view of the layout structure of respective elements formed in the semiconductor chip 4. Referring to FIG. 4, the chip 4 includes a CPU (Central Processing Unit) 12, a ROM (Read Only Memory) 13, a RAM (Random Access Memory) 14, an EEPROM (Electrically Erasable Programmable Read Only Memory) 15, an analog circuit 16, and bonding pads 17.

The CPU (circuit) 12 is called a central processing unit, and is the heart of a computer. The CPU 12 reads a command from a storage device and interprets it to perform various kinds of computations and control based on the command. For this reason, high-speed processing is required for the CPU 12. A MISFET (metal insulator semiconductor field effect transistor) included in the CPU 12 among the elements formed over the semiconductor chip 4 needs a relatively high current driving capability. In other words, the CPU 12 is formed of the MISFET having a low withstand voltage.

The ROM (circuit) 13 is a memory which stores data therein in permanent form with no ability to alter the data. It is called a read only memory. The ROM 13 has two types of structures, that is, a NAND type in which the MISFETs are connected in series, and a NOR type in which the MISFETs are connected in parallel. The NAND type is used when a high packaging density is required, whereas the NOR type is frequently used when a high operation speed is required. Since the high-speed operational performance is also required for the ROM 13, the MISFETs constituting the ROM 13 must have a relatively high current driving capability. In other words, the ROM 13 is formed of the MISFETs having a low withstand voltage.

The RAM (circuit) 14 is a memory that can read the stored data and write new data in a random manner, that is, as needed. It is called a random access memory that permits random reading and writing. The RAM 14 serving as the IC memory is available in two types, namely, a DRAM (Dynamic RAM) using a dynamic circuit, and a SRAM (Static RAM) using a static circuit. The DRAM is a memory that permits the random reading and writing which requires a storage operation, and the SRAM is a memory that permits the random reading and writing which does not requiring the storage operation. Since the high-speed operational performance is also required for the RAM 14, the MISFETs constituting the RAM 14 need a relatively high current driving capability. In other words, the RAM 14 is formed of the MISFETs having a low withstand voltage.

The EEPROM 15 is one kind of nonvolatile memories that can electrically rewrite so as to enable writing and erasing operations. It is called an electrically erasable programmable read only memory. A memory cell of the EEPROM 15 is composed of, for example, a MONOS (Metal Oxide Nitride Oxide Semiconductor) type transistor, and a MNOS (Metal Nitride Oxide Semiconductor) type transistor, for storage (memory). The writing and erasing operations of the EEPROM 15 makes use of, for example, Fowler-Nordheim tunneling. It should be noted that the writing and erasing operations are also possible using hot electrons and hot holes.

Upon writing to the EEPROM 5, a high potential difference (about 12V) is produced in the MONOS transistor for storage, so that a transistor with a relatively high withstand voltage is required as the MONOS transistor for storage.

The analog circuit 16 is a circuit for dealing with signals of a voltage or current which is changed continuously with the passage of time, that is, analog signals. The analog circuit 16 has, for example, an amplification circuit, a conversion circuit, a modulation circuit, an oscillation circuit, a power supply circuit, and the like. Among the elements formed over the chip 4, a MISFET having a relatively high withstand voltage is used for these analog circuits 16.

The bonding pad 17 is an electrode for external connection. In other words, the integrated circuit formed in the semiconductor chip 4 is connected to the outside via the bonding pads 17. For example, the bonding pad 17 is connected to the bonding wire 5b shown in FIG. 2, and the bonding wire 5b is connected to the land of the package substrate 5a. In this way, the semiconductor chip 4 is electrically connected to the outside via the bonding pads 17.

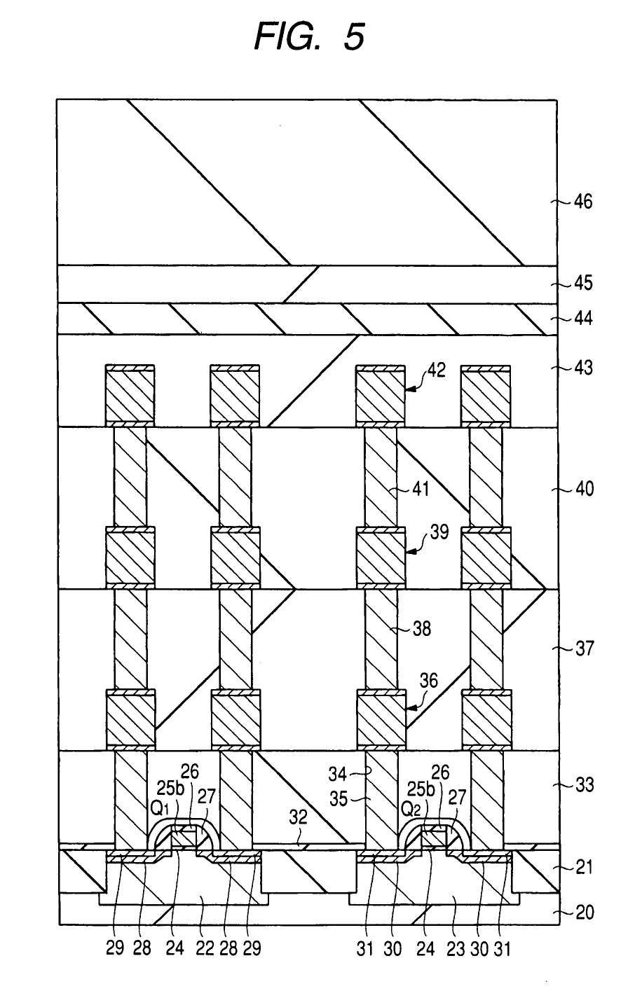

Now, an example of the structure of elements formed inside the semiconductor chip 4 will be described with reference to FIG. 5. FIG. 5 is a sectional view showing the structure of the semiconductor device according to the first embodiment. FIG. 5 shows a section of an area in which a CMISFET (Complementary Metal Insulator Semiconductor Field Effect Transistor) is formed.

In FIG. 5, element separation regions 21 are formed on a semiconductor substrate 20 made of, for example, silicon single crystal. The element separation region 21 is provided for separating the elements and for preventing interference between those elements. Each element is formed in an active region separated by the element separation regions 21.

Among the active regions separated by the element separation regions 21, a p-type well 22 is formed in an n-channel type MISFET forming region, and an n-type well 23 is formed in a p-channel type MISFET forming region. The p-type well 22 is a semiconductor region of the semiconductor substrate 20 into which p-type impurities, such as boron (B), are introduced, whereas the n-type well 23 is a semiconductor region of the semiconductor substrate 20 into which n-type impurities, such as phosphorus (P) or arsenic (As), are introduced.

First, the structure of the n-channel type MISFETQ1 formed over the p-type well 22 will be described below. In the n-channel type MISFETQ1, a gate insulating film 24 made of, for example, a silicon oxide film, is formed on the p-type well 22. On the gate insulating film 24, a gate electrode 25a made of, for example, a polysilicon film, is formed. A cap insulating film 26 for protecting the gate electrode 25a is formed on the gate electrode 25a. The cap insulating film 26 is formed of, for example, a silicon oxide film.

Side walls 27 are formed on both side walls of the gate electrode 25a. Semiconductor diffusion regions 28 containing a low concentration of n-type impurities are formed under the side walls 27 over the semiconductor substrate 20. Diffusion regions 29 containing a high concentration of n-type impurities are formed, matched with the side walls 27. The side wall 27 is made of an insulating film, such as a silicon oxide film. The low-concentration n-type impurity diffusion region 28 and the high-concentration n-type impurity diffusion region 29 have the n-type impurities, such as phosphorus or arsenic, introduced thereto. The diffusion region 28 and the diffusion region 29 form a source region and a drain region of a LDD (Lightly Doped Drain) structure, respectively. The high-concentration n-type impurity diffusion region 29 has the n-type impurities introduced thereto in a higher concentration than the low-concentration n-type impurity diffusion region 28.

Then, the structure of the p-channel type MISFET Q2 formed over the n-type well 23 will be described below. In the p-channel type MISFETQ2, the gate insulating film 24 made of, for example, a silicon oxide film, is formed on the n-type well 23. On the gate insulating film 24, a gate electrode 25b made of, for example, a polysilicon film, is formed. The cap insulating film 26 is formed on the gate electrode 25b to protect the electrode 25b. The cap insulating film 26 is formed of, for example, a silicon oxide film.

On both side walls of the gate electrode 25b, other side walls 27 are formed. Semiconductor diffusion regions 30 containing a low concentration of p-type impurities are formed under the side walls 27 over the semiconductor substrate 20. Diffusion regions 31 containing a high concentration of p-type impurities are formed, matched with the side walls 27. The side wall 27 is made of an insulating film, such as a silicon oxide film. The low-concentration p-type impurity diffusion region 30 and the high-concentration p-type impurity diffusion region 31 have the p-type impurities, such as phosphorus, introduced thereto. The low-concentration p-type impurity diffusion region 30 and the high-concentration p-type impurity diffusion region 31 form a source region and a drain region of a LDD structure, respectively. The high-concentration p-type impurity diffusion region 31 has the p-type impurities introduced thereto in a higher concentration than the low-concentration p-type impurity diffusion region 30.

Although not shown, a metal silicide layer made of, for example, cobalt silicide or the like, may be formed on the gate electrodes 25a and 25b, the high-concentration n-type impurity diffusion region 29, and the high-concentration p-type impurity diffusion region 31 of the first embodiment. In this case, the cap insulating films 26 are not formed on the gate electrodes 25a and 25b. Formation of such a metal silicide layer can decrease the surface contact resistance. Note that other materials of the metal silicide layer may include, for example, nickel silicide, titanium silicide, and the like.

In this way, the n-channel type MISFETQ1 and the p-channel type MISFETQ2 are formed over the semiconductor substrate 20. Next, the structure of wirings formed above the n-channel type MISFETQ1 and the p-channel type MISFETQ2 will be described below.

A silicon nitride film 32 and a silicon oxide film 33 are formed over the n-channel type MISFETQ1 and the p-channel type MISFETQ2. The silicon nitride film 32 and the silicon oxide film 33 form an interlayer insulating film, in which a contact hole 34 is formed. The bottom of the contact hole 34 reaches the high-concentration n-type impurity diffusion region 29 or the high-concentration p-type impurity diffusion region 31.

Inside the contact hole 34, a conductive film is embedded to form a plug 35. The plug 35 is formed of a laminated film of, for example, a barrier conductive film and a tungsten film. The barrier conductive film has a function of preventing spread of the tungsten constituting the tungsten film to the outside of the plug 35. The barrier conductive film is formed of, for example, a laminated film of a titanium coating and a titanium nitride coating (hereinafter referred to as a titanium/titanium nitride film).

Wirings 36 serving as a first wiring layer are formed above the plugs 35 to be electrically connected to the plugs 35. The wiring 36 is formed of a laminated film consisting of, for example, a titanium/titanium nitride film, an aluminum film, and a titanium/titanium nitride film. Note that instead of the aluminum film, an aluminum alloy film may be used.

Then, a silicon oxide film 37 serving as the interlayer insulating film is formed to cover the wirings 36, and a plug 38 is formed to penetrate the silicon oxide film 37. The bottom of the plug 38 reaches the wiring 36. Wirings 39 serving as a second wiring layer are formed above the plugs 38.

A silicon oxide film 40 serving as the interlayer insulating film is formed to cover the surroundings of the wirings 39, and a plug 41 is formed to penetrate the silicon oxide film 40. The bottom of the plug 41 reaches the wiring 39, and the plug 41 and the wiring 39 are electrically connected to each other.

Wirings 42 serving as the uppermost wiring layer are formed above the plugs 41 to be electrically connected to the plugs 41. And, a silicon oxide film 43 is formed to cover the surroundings of the wirings 42. A colored thin film 44 is formed on the oxide silicon film 43, and a silicon oxide film 45 is formed on the colored thin film 44. A silicon nitride film 46 serving as a surface protective film is formed on the silicon oxide film 45. The surface protective film is a film formed as the uppermost layer, and has a function of protecting the semiconductor chip from mechanical stress and impurity incorporation. Although in FIG. 5 the number of wiring layers is three, this is illustrative, and the invention is not limited thereto. The invention can be applied to cases where the number of wiring layers is greater than, or less than, or equal to three.

One of the features according to the first embodiment is that the colored thin film 44 is provided. In other words, the semiconductor device includes the uppermost wiring layer (wiring 42) formed over the semiconductor substrate 20, the interlayer insulating film (the silicon oxide film 43 and the silicon oxide film 45) formed over the uppermost wiring layer, and the surface protective film (silicon nitride film 46 formed over the interlayer insulating film. The semiconductor device is characterized by that the colored thin film 44 for attenuating visible light and laser light in a specific wavelength region is formed in the interlayer insulating film.

Thus, the formation of the colored thin film 44 can render the wiring pattern formed under the thin film 44 invisible. This makes it difficult to read out the layout information of the multilayer wiring formed inside the semiconductor chip, and hence to analyze the integrated circuit formed inside the chip. That is, the semiconductor chip used in the IC card or the like can ensure the high security of the information.

In the known semiconductor device, no colored thin film is formed in the interlayer insulating film. That is, a silicon oxide film is used in the interlayer insulating film, and a silicon nitride film is used as the surface protective film. Since the silicon oxide film and the silicon nitride film can transmit the visible light, the wiring pattern formed as an underlayer can be viewed using, for example, a microscope or the like. The wiring pattern is read out and the integrated circuit formed in the semiconductor chip is analyzed, which may lead to abuse, including unauthorized falsification.

In order to improve the security of the semiconductor chip, a technique is known which involves forming a relatively large solid pattern covering one functional module, thereby rendering the functional module present under the solid pattern less identifiable. This technique has a high effect of cutting off the light, such as laser light or flash light, but the solid pattern can be removed relatively easily by the physical method. Furthermore, the so-called active shield technique is proposed which involves laying a wiring pattern formed adjacent to the power source wiring and the GND wiring, and forcefully resetting an integrated circuit formed in a semiconductor chip when either an open or a short is electrically detected. In this technique, when the wiring pattern is intended to be removed by the physical method, the open or short is detected to reset the integrated circuit. It is understood that the technique has high resistance to the physical attack. However, since the light is transmitted through the space between the wirings, the active shield technique has a susceptibility to the attack using the light. In other words, the active shield technique has less resistance to the measures that causes the IC card to malfunction by irradiating the semiconductor chip with the laser light and feeding current through a pn junction formed over the chip. Likewise, another technique is proposed which involves forming dummy patterns or dummy wirings so as to make it difficult to read the information on the layout of the multilayer wiring. This technique has a susceptibility to the attack using the light because the light is transmitted from a space between the wirings.

To cope with the attack using the light, a further technique is known which involves providing a light detector within a semiconductor chip. However, the number of the light detectors which can be provided in the chip is limited. If the restricted beam, such as collected light or laser light, is applied to the chip avoiding the positions of the light detectors, it cannot be detected by those detectors. Moreover, a still further technique is known in which a light blocking material is provided outside the surface protective film. In this technique, however, the light blocking material can be removed easily without having any influence on the semiconductor chip itself.

In the first embodiment, as shown in FIG. 5, the colored thin film 44 is provided in the interlayer insulating film. The colored thin film 44 has a function of attenuating the visible light, which is a first function. The term “visible light” means light having a wavelength of 380 nm or more and 800 nm or less. The colored thin film 44 does not attenuate the visible light in the entire wavelength range, and may have a function of attenuating part of the visible light. That is, the colored thin film 44 may be not only a block one, but also one in other colors (any appropriate colored one). In other words, the colored thin film 44 may be nontransparent to allow the light in the entire wavelength range of the visible light to pass therethrough. Since this kind of colored thin film 44 is provided in the interlayer insulating film, the wiring patterns (the wiring 42, the wiring 39, and the wiring 36) formed under the colored thin film 44 cannot be read out even when observing the semiconductor chip with the microscope or the like. This makes it difficult to analyze the integrated circuit formed in the semiconductor chip, thereby improving the security of the semiconductor chip.

The colored thin film 44 has a function of attenuating the laser light in the specific wavelength range, which is a second function. Thus, even when the laser light is applied to the semiconductor chip, the laser light does not reach the pn junction formed over the semiconductor substrate 20, thereby preventing the malfunction of the semiconductor device which may be caused by the current passing through the pn junction. That is, the colored thin film 44 is provided as an upper layer positioned over the semiconductor substrate 20. The colored thin film 44 attenuates and blocks the laser light, so that the laser light can be prevented from being applied to the pn junction formed over the semiconductor substrate 20. The specific wavelength region of the laser light is a wavelength range of, for example, 500 nm or more and 600 nm or less. For example, the thin film 44 has the attenuation function of the laser light having a wavelength of 532 nm. Furthermore, the specific wavelength region of the laser light is not limited thereto. The thin film may have the function of attenuating of the laser light having a wavelength of, for example, 266 nm, 355 nm, or 1064 nm. That is, the thin film 44 may have the attenuation function of the laser light, such as Nd:YAG laser, which is generally used industrially.

As mentioned above, the colored thin film 44 of the first embodiment has the first and second functions, thereby improving the resistance to the attack using the light. In particular, the colored thin film 44 is formed over the entire main surface of the semiconductor substrate 20, and hence has an advantage in that there is no space through which the light is transmitted. Thus, even when the restricted beam, such as the laser light, is applied, the greater light blocking effect can be obtained.

One of the features of the first embodiment of the invention is that the colored thin film 44 is formed between the wiring 42 constituting the uppermost wiring layer and the silicon nitride film 46 serving as the surface protective film. In other words, the silicon oxide films 43 and 45 each serving as the interlayer insulating film are formed between the wiring 42 and the silicon nitride film 46, and the colored thin film 44 is formed between the silicon oxide film 43 and the silicon oxide film 45. Such formation of the colored thin film 44 above the wiring 42 makes it impossible to read all the wiring patterns provided by the wirings 42, the wirings 39 and the wirings 36. Furthermore, the element forming patterns formed over the semiconductor substrate 20 (the n-channel type MISFETQ1, the p-channel type MISFETQ2, the memory cell, and the like) cannot be read out. Thus, the security of the semiconductor chip can be improved.

On the other hand, the formation of the colored thin film 44 under the silicon nitride film 46 serving as the surface protective film can improve the resistance to the physical attack. That is, in the known structure disclosed in, for example, Japanese Unexamined Patent Publication No. 2000-183291, as described in the related art, the colored thin film 44 is formed above the silicon nitride film 46 serving as the surface protective film. The colored thin film 44 will be able to be removed without affecting the semiconductor chip. In contrast, as described in the first embodiment, since the colored thin film 44 is formed under the silicon nitride film 46, first the silicon nitride film 46 serving as the surface protective film needs to be removed. After removing the silicon oxide film 45, the colored thin film 44 is removed. At this time, the wiring 42 and the like may be damaged, which leads to inconvenience in analysis of the pattern by the wiring 42. The formation of the colored thin film 44 under the silicon nitride film 46 renders the removal of the film 44 difficult without affecting the semiconductor chip. In other words, this can improve the resistance to the physical attack to the colored thin film 44.

As mentioned above, the provision of the colored thin film 44 can improve the resistance to the attack using the light. Furthermore, since the colored thin film 44 is disposed under the silicon nitride film 46 serving as the surface protective film, the resistance to the physical attack can be improved.

Subsequently, the material used in the colored thin film 44 will be described below. First of all, the colored thin film 44 can be made using a colored insulating film. The colored insulating film may include, for example, a silicon oxide film into which a metal oxide is added. More specifically, the silicon oxide film is formed of a SOG (Spin On Glass) film, which is made of the SOG. When forming the SOG film, cobalt oxide is mixed as the metal oxide thereby to form the colored insulating film. At this time, the thickness of the colored insulating film is required to block off a part or the whole of the visible light and the laser light in the specific wavelength region, and is, for example, 100 nm or more and 2 μm or less, which can provide a sufficient effect of blocking the light. Since the colored thin film 44 is formed of the silicon oxide film containing the cobalt oxide, the thin film 44 becomes difficult to be removed with the FIB or the like, so that the security of the semiconductor device can be improved. That is, if the colored thin film 44 is formed of a metal film and so on, like the solid pattern, it can be removed easily using a physical method, such as the FIB. However, like the silicon oxide film containing the cobalt oxide, mixing the colored material into the silicon oxide film itself can make it difficult to remove the colored thin film. This can ensure the security of the semiconductor device.

Furthermore, a colored conductive film can be used as the colored thin film 44. Since in the first embodiment, the colored thin film 44 is positioned above the wiring 42 serving as the uppermost wiring layer, the colored conductive film can also be used as the film 44. The colored conductive film may include, for example, a graphite (carbon) film. The graphite film is black in color, and hence can block sufficiently the visible light and the laser light in the specific wavelength range. For example, when the graphite film is used as the colored thin film 44, the film 44 having a thickness of, for example, 30 nm or more and 50 nm or less, can provide the sufficient effect. The graphite film can be formed using a plasma CVD (Chemical Vapor Deposition) method, for example.

The semiconductor device according to the first embodiment of the invention is constructed as mentioned above, and a method of manufacturing the same will be described below with reference to the accompanying drawings.

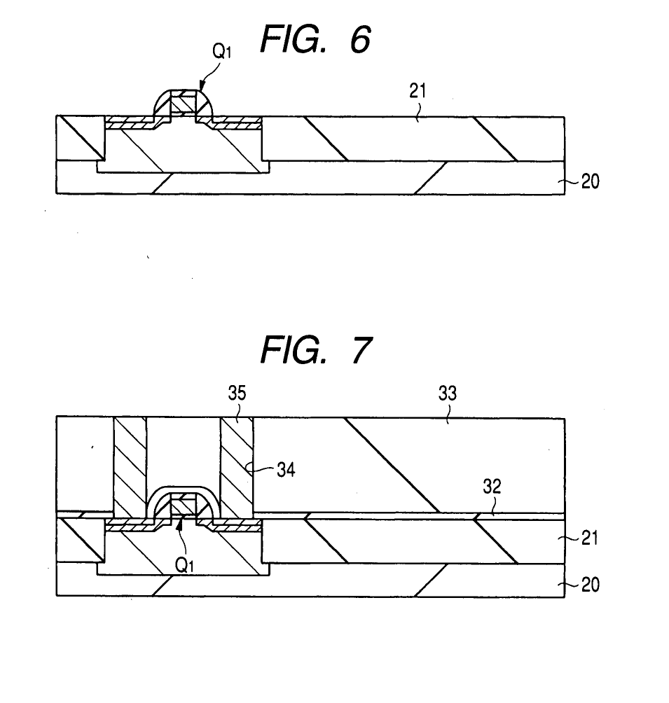

First, as shown in FIG. 6, the element separation regions 21 are formed in the semiconductor substrate 20. The element separation region 21 can be formed using, for example, a STI (Shallow Trench Isolation) method. That is, the element separation region 21 can be formed by forming an element separation groove in the semiconductor substrate 20, embedding a silicon oxide film into the groove, and grinding the film using a CMP (Chemical Mechanical Polishing) method. In an active region separated by the element separation regions 21, the n-channel type MISFETQ1 is formed using a normal technique. Similarly, the p-channel type MISFETQ2 is also formed, but the representation thereof is omitted.

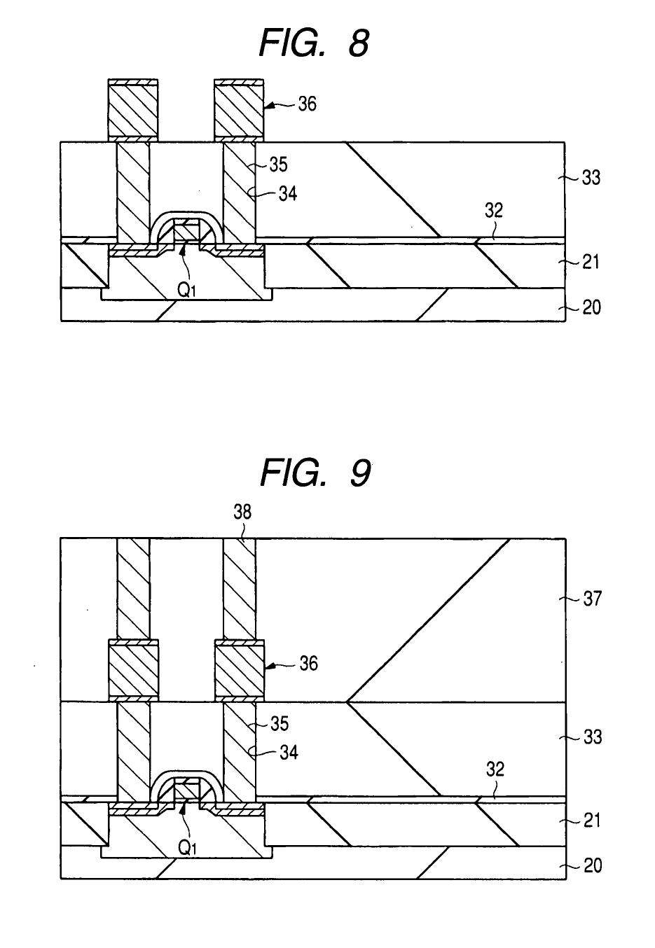

Then, as shown in FIG. 7, the silicon nitride film 32 is formed over the semiconductor substrate 20 on which the n-channel type MISFETQ1 is formed, and the silicon oxide film 33 is formed on the silicon nitride film 32. The silicon nitride film 32 and the silicon oxide film 33 can be formed using, for example, the CVD method. The silicon nitride film 32 and the silicon oxide film 33 form the interlayer insulating film. Subsequently, contact holes 34 are formed to penetrate the silicon oxide film 33 and the silicon nitride film 32 using a photolithography technique and an etching technique. A laminated film consisting of a titanium/titanium nitride film and a tungsten film is formed on the silicon oxide film 33 including the inside of the contact hole 34. The titanium/titanium nitride film can be formed using, for example, a sputtering method, and the tungsten film can be formed using, for example, the CVD method. Thereafter, the unnecessary titanium/titanium nitride and tungsten films formed on the silicon oxide film 33 are removed using the CMP method to form the plugs 35.

Subsequently, as shown in FIG. 8, the titanium/titanium nitride film, the aluminum film, and the titanium/titanium nitride film are formed on the silicon oxide film 33 with the plugs 35 formed therein. These laminated films can be formed using, for example, the sputtering method. The laminated films are patterned using the photolithography technique and the etching technique to form the wiring 36 constituting the first wiring layer. Note that instead of the aluminum film, an aluminum alloy film may be formed.

Then, as shown in FIG. 9, the silicon oxide film 37 is formed on the silicon oxide film 33 on which the wirings 36 are formed. The silicon oxide film 37 is the interlayer insulating film, and can be formed using, for example, the CVD method. Connection holes are formed in the silicon oxide film 37 using the photolithography technique and the etching technique. Then, a lamination consisting of the titanium/titanium nitride film and the tungsten film is formed to be embedded into the connection holes, and the unnecessary titanium/titanium nitride and tungsten films formed on the silicon oxide film 37 are removed by the CMP method to form the plugs 38. The plug 38 is formed so as to be electrically connected to the wiring 36.

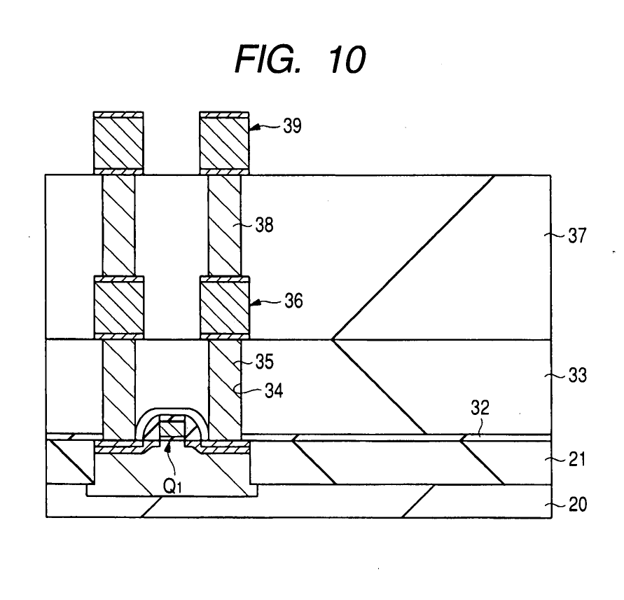

Subsequently, as shown in FIG. 10, the titanium/titanium nitride film, the aluminum film, and the titanium/titanium nitride film are formed on the silicon oxide film 37 with the plugs 38 formed therein. These films laminated can be formed using, for example, the sputtering method. The laminated films are patterned using the photolithography technique and the etching technique to form the wiring 39 constituting the second wiring layer.

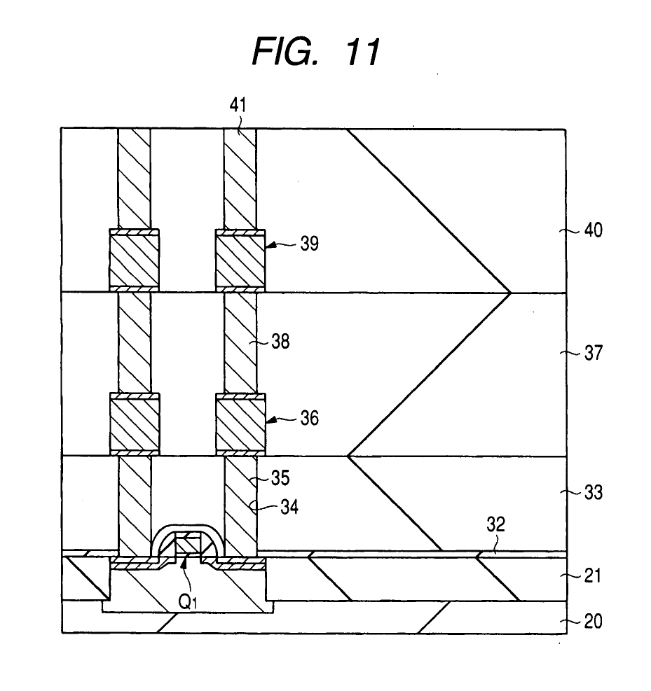

Then, as shown in FIG. 11, the silicon oxide film 40 is formed on the silicon oxide film 37 with the wirings 39 formed thereon. The silicon oxide film 40 is the interlayer insulating film, and can be formed using, for example, the CVD method. Connection holes are formed in the silicon oxide film 40 using the photolithography technique and the etching technique. Then, a lamination consisting of the titanium/titanium nitride film and the tungsten film is formed to be embedded into the connection holes, and the unnecessary titanium/titanium nitride and tungsten films formed on the silicon oxide film 40 are removed by the CMP method thereby to form the plugs 41. The plug 41 is formed to be electrically connected to the wiring 39.

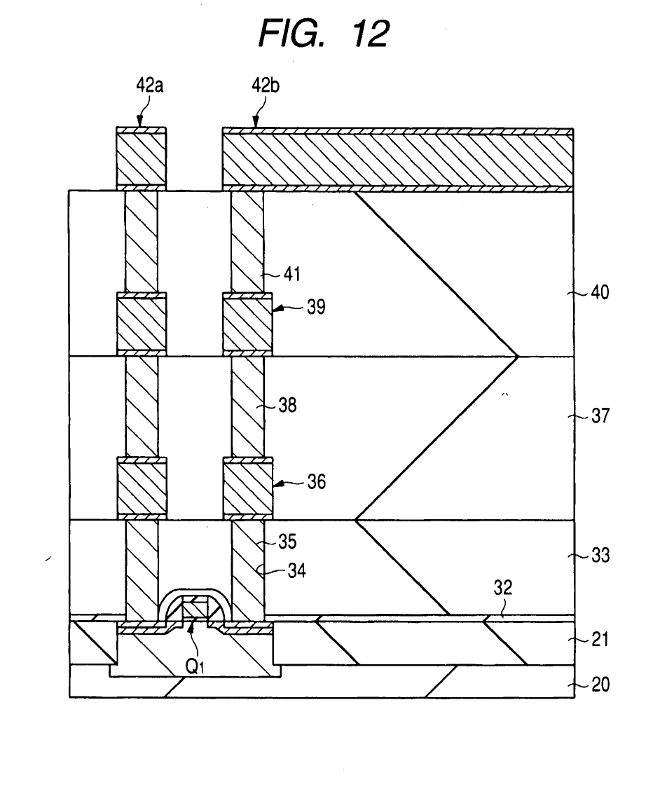

Subsequently, as shown in FIG. 12, the titanium/titanium nitride film, the aluminum film, and the titanium/titanium nitride film are formed over the silicon oxide film 40 with the plugs 41 formed therein. These laminated films can be formed using, for example, the sputtering method. The laminated films are patterned using the photolithography technique and the etching technique to form the wirings 42a and 42b constituting the uppermost wiring layer.

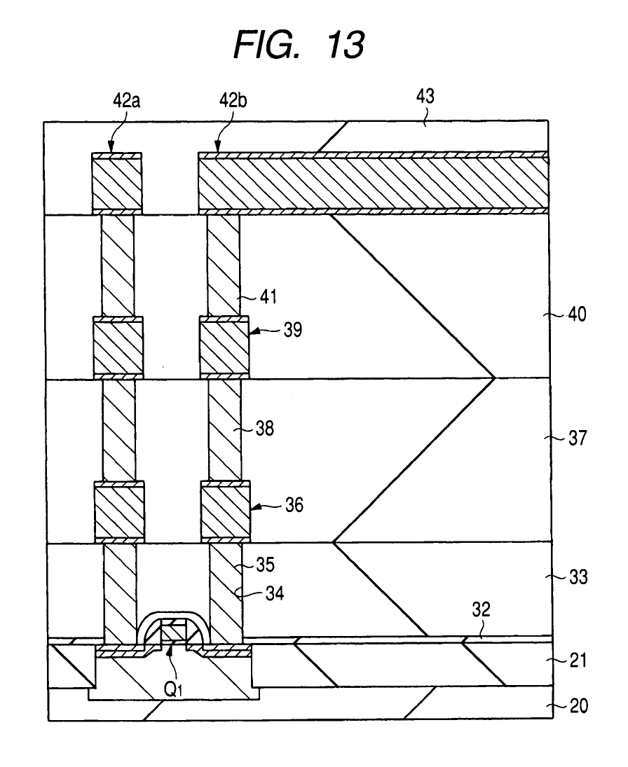

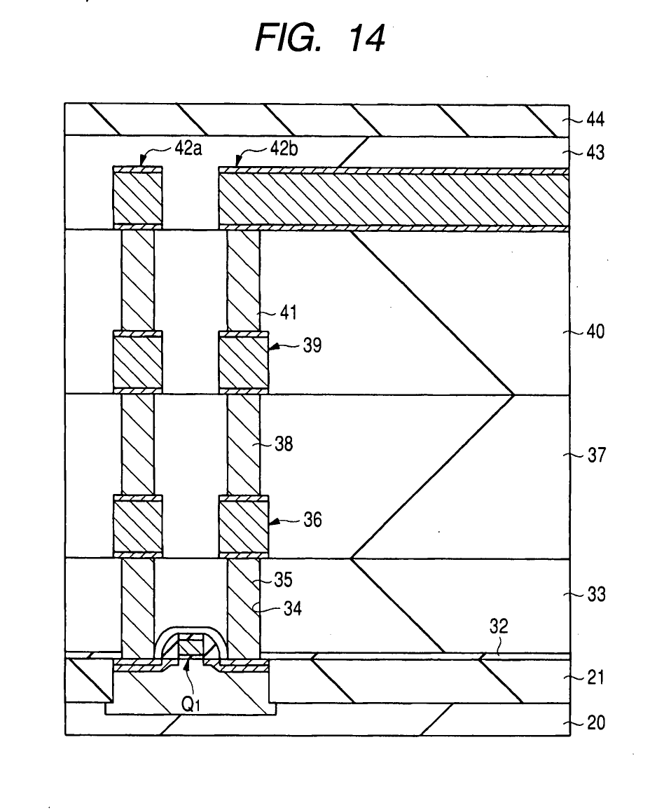

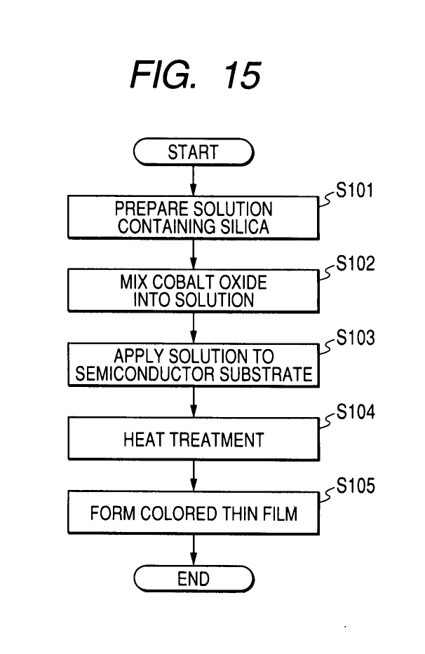

Then, as shown in FIG. 13, the silicon oxide film 43 is formed over the silicon oxide film 40 to cover the wirings 42a and 42b. The silicon oxide film 43 can be formed using, for example, the CVD method. As shown in FIG. 14, the colored thin film 44 for attenuating the visible light and the laser light in the specific wavelength range is formed on the silicon oxide film 43. As an example of the colored thin film 44, the formation of the silicon oxide film containing the cobalt oxide will be described below with reference to FIG. 15. Reference will be made to a case where the silicon oxide film containing the cobalt oxide is formed as one example of the colored thin film 44 based on FIG. 15.

First, a solution into which silica is dissolved is prepared (step S101). The cobalt oxide is mixed into the solution with the silica dissolved thereto (step S102). Thereafter, the solution containing the cobalt oxide and the silica is applied to the silicon oxide film 43 (over the semiconductor substrate 20) (step S103). Then, heat treatment is applied to the semiconductor substrate 20 (step S104). This can form the colored thin film 44 composed of the silicon oxide film (SOG film) containing the cobalt oxide (step S105). At this time, the colored thin film 44 is formed to have a thickness of 100 nm or more and 2 μm or less. When the colored thin film 44 with such a thickness cannot be formed in one-time process, the process shown in FIG. 15 is carried out a plurality of times to achieve the film 44 of 100 nm to 2 μm in thickness.

Although the silicon oxide film containing the cobalt oxide has been described above as one example of the colored thin film 44, for example, a graphite film may be formed as the colored thin film 44. In formation of the graphite film, for example, the plasma CVD method can be used. At this time, the graphite film is formed to have a thickness of 30 nm or more and 50 nm or less.

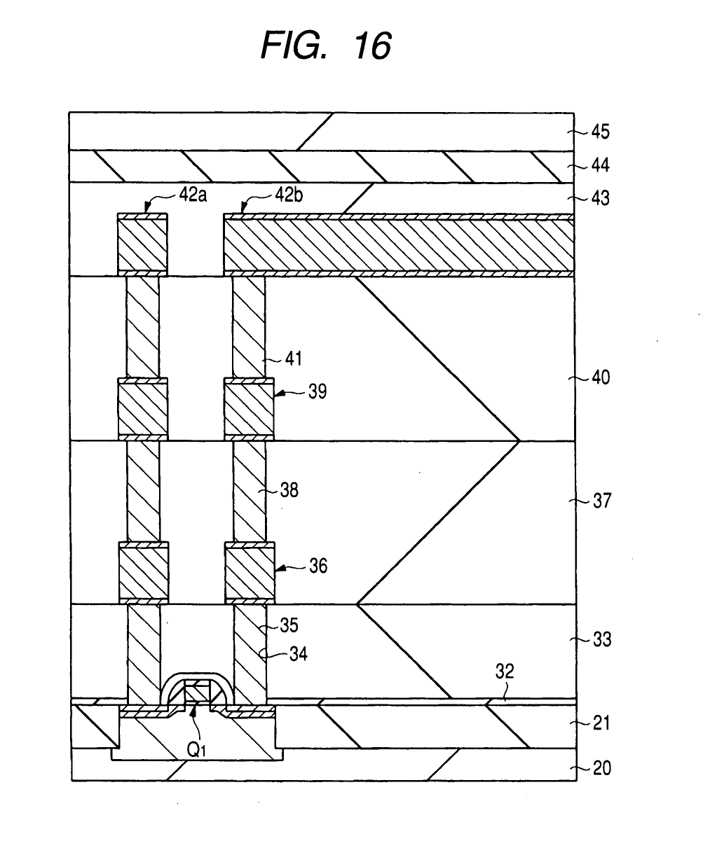

Then, as shown in FIG. 16, the silicon oxide film 45 is formed on the colored thin film 44. The silicon oxide film 45 can be formed using, for example, the CVD method. The silicon oxide film 43 and the silicon oxide film 45 serve as the interlayer insulating film, and the colored thin film 44 is formed in the interlayer insulating film.

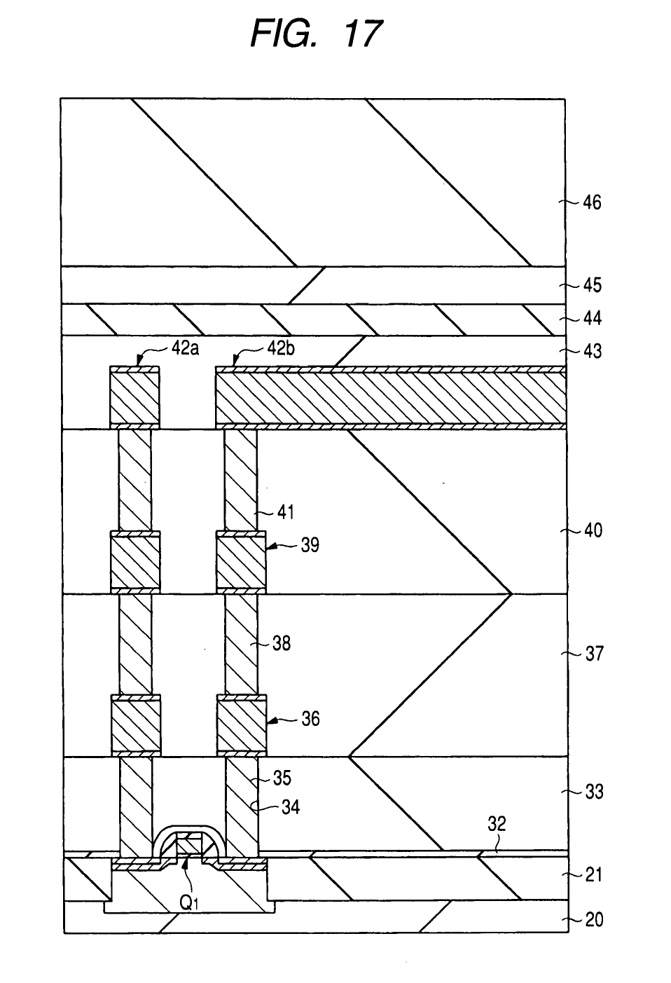

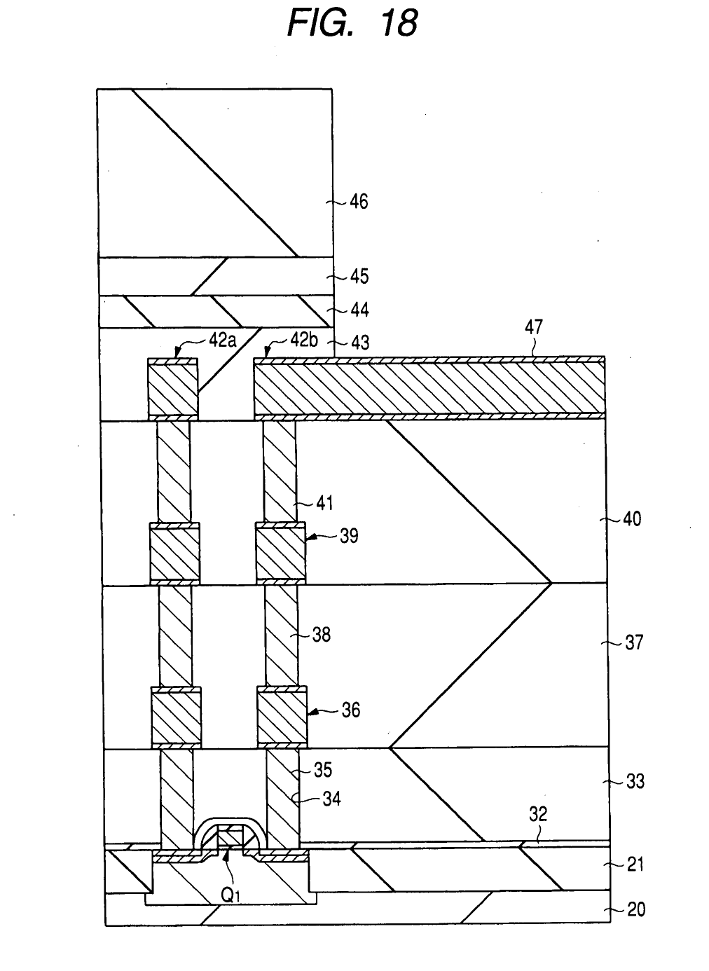

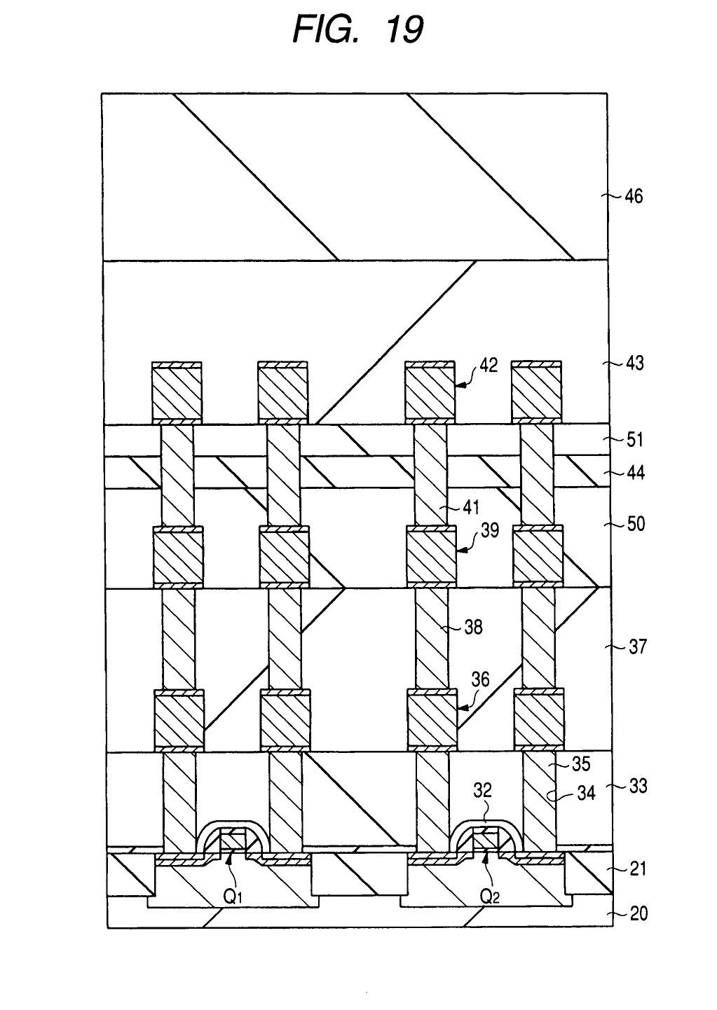

Subsequently, as shown in FIG. 17, the silicon nitride film 46 is formed on the silicon oxide film 45. The silicon nitride film 46 serves as the surface protective film for preventing the intrusion of contaminant, moisture, or the like from the outside, and can be formed using, for example, the CVD method. As shown in FIG. 18, an opening penetrating the silicon oxide film 43, the colored thin film 44, the silicon oxide film 45, and the silicon nitride film 46 is formed using the photolithography technique and the etching technique. At this time, a part of the wiring 42b is exposed at the bottom of the opening to form the bonding pad 47.

In this way, the semiconductor device according to a first embodiment can be formed.

According to the first embodiment, the colored thin film 44 is provided between the uppermost wiring layer and the surface protective film, thereby improving the resistance to the attack using the light as well as the resistance to the attack using the physical method. Since the colored thin film 44 is constituted of the silicon oxide film containing the cobalt oxide, only a step of mixing the cobalt oxide is added to the normal manufacturing steps of the silicon oxide film (SOG film), advantageously forming the colored thin film 44. Therefore, according to the first embodiment of the invention, the security of the semiconductor device can surely be improved with low manufacturing cost. Similarly, also in use of the graphite film as the colored thin film, it can be formed using the plasma CVD method, which may be used in the normal manufacturing step, so that the security of the semiconductor device can surely be improved with low manufacturing cost.

### Second Preferred Embodiment

In the above description of one example of the first embodiment, the colored thin film is formed in the interlayer insulator or insulating film formed between the uppermost wiring layer and the surface protective film. In a second preferred embodiment, the colored thin film is formed in the interlayer insulator or insulating film formed between the wiring layers, which will be described below.

FIG. 19 is a sectional view showing a section of a semiconductor device according to the second embodiment. Referring to FIG. 19, the second embodiment differs from the first embodiment in that the colored thin film 44 is formed between the wiring 39 constituting the second wiring layer and the wiring 42 constituting the uppermost wiring layer. That is, although in the first embodiment, the colored thin film 44 is formed above the uppermost wiring layer, the colored thin film 44 may be formed in the interlayer insulating film between the second wiring layer and the uppermost wiring layer in the second embodiment. In other words, the silicon oxide film 50 is formed on the wirings 39, and the colored thin film 44 is formed on the silicon oxide film 50. The silicon oxide film 51 is formed on the colored thin film 44, and the wirings 42 are formed on the silicon oxide film 51.

Even when the colored thin film 44 is formed in this way, the security of the semiconductor device can be improved. This is because the colored thin film 44 attenuates and blocks the visible light, and the layout structure of the wiring patterns (the wiring 39 and the wiring 36) under the colored thin film 44 becomes difficult to be read. Furthermore, since the colored thin film 44 attenuates and blocks the laser light in the specific wavelength region, the pn junction or the like formed over the semiconductor substrate 20 can be prevented from being irradiated with the laser light, thus making it difficult to analyze the information based on the malfunction of the semiconductor device.

In the second embodiment, since the uppermost wiring layer is formed above the colored thin film 44, the uppermost wiring layer itself is not protected by the colored thin film 44. However, the wiring 39 and the wiring 36 formed under the colored thin film 44 are difficult to view. Thus, all wirings constituting the integrated circuit cannot be analyzed, so that the security is ensured without problems. That is, even if all wirings are not difficult to read out, the security of the semiconductor device can be ensured by rendering a part of the wiring difficult to read.

Furthermore, in the second embodiment, since the colored thin film 44 is positioned in a lower position than in the first embodiment, it is more difficult to remove the colored thin film 44, thereby improving the resistance to the physical attack. In other words, in the second embodiment, in order to remove the colored thin film 44, it is necessary to remove the silicon nitride film 46, the silicon oxide film 43, the wiring 42, the silicon oxide film 51, and the like. The removal of the colored thin film 44 involves complicated steps. Furthermore, in order to remove the colored thin film 44, it is required to remove the wiring 42. Even if the colored thin film 44 is removed, the semiconductor device cannot operate normally, which can make the analysis of the information difficult.

Now, the material of the colored thin film 44 will be described below. In the second embodiment, as shown in FIG. 19, the colored thin film 44 is brought into contact with the plugs 41. Thus, the colored thin film 44 is desirably made of an insulating film. If the colored thin film were made of a conductive film, it would bright all plugs 41 into conduction. Accordingly, the colored thin film 44 can be formed of, for example, the silicon oxide film containing the cobalt oxide.

The semiconductor device of the second embodiment is constructed as mentioned above, and a method of manufacturing the same will be described below with reference to the accompanying drawings.

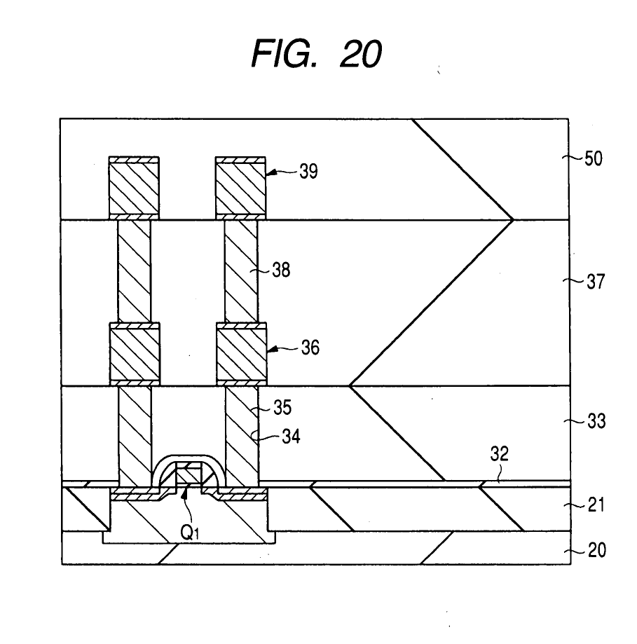

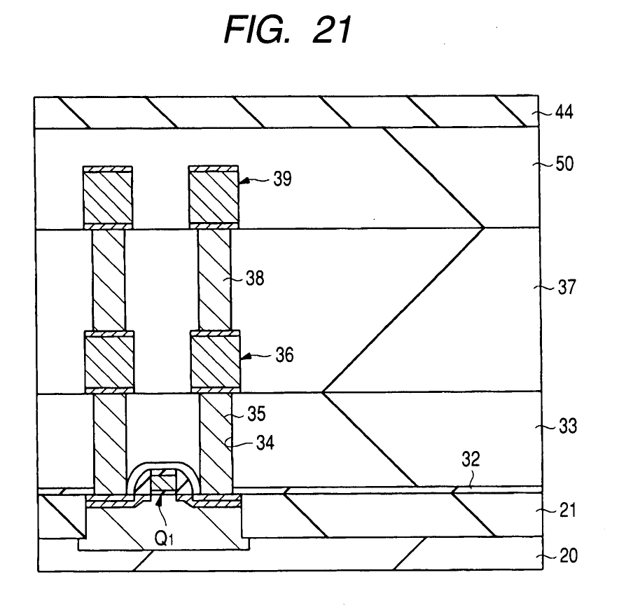

The steps of FIGS. 6 to 10 in the second embodiment are the same as those in the first embodiment. Subsequently, as shown in FIG. 20, the silicon oxide film 50 is formed on the silicon oxide film 37 including the wirings 39. The silicon oxide film 50 is the interlayer insulating film, and can be formed using, for example, the CVD method. Then, as shown in FIG. 21, the colored thin film 44 is formed on the silicon oxide film 50. The colored thin film 44 can be formed of, for example, the silicon oxide film containing the cobalt oxide. The manufacturing process of the silicon oxide film containing the cobalt oxide can be the same as that in the first embodiment. That is, a solution into which silica is dissolved is first prepared. The cobalt oxide is mixed into the solution with the silica dissolved thereto. Thereafter, the solution containing the cobalt oxide and the silica is applied to the silicon oxide film 50 (over the semiconductor substrate 20). Then, heat treatment is applied to the semiconductor substrate 20. This can form the colored thin film 44 composed of the silicon oxide film (SOG film) which contains the cobalt oxide. The colored thin film 44 is formed to have a thickness of 100 nm or more and 2 μm or less.

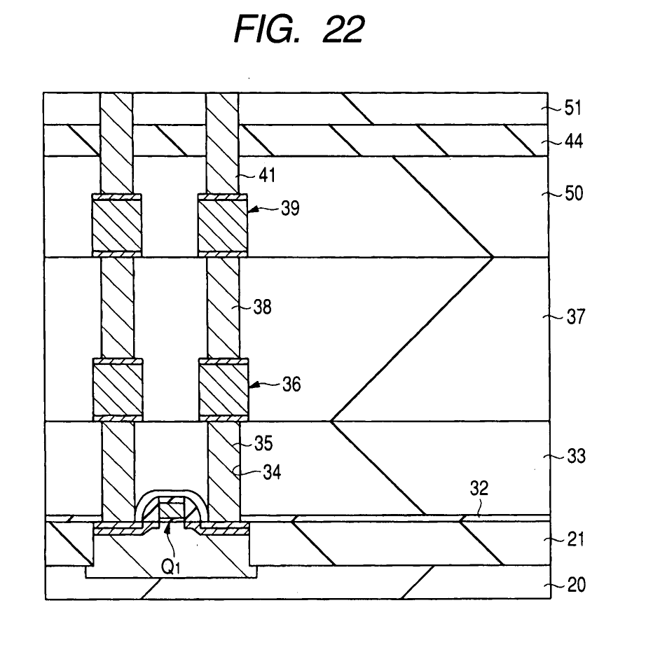

Then, as shown in FIG. 22, the silicon oxide film 51 is formed on the colored thin film 44 using, for example, the CVD method. Connection holes are formed to reach the oxide silicon film 50 through the silicon oxide film 51 and the colored thin film 44 using the photolithography technique and the etching technique. At this time, the wiring 39 is exposed at the bottom of the connection hole. The silicon oxide film 50 and the silicon oxide film 51 serve as the interlayer insulating film in which the colored thin film 44 is formed.

Subsequently, a laminated film consisting of the titanium/titanium nitride film and the tungsten film is formed to be embedded into the connection holes, and the unnecessary titanium/titanium nitride and tungsten films formed on the silicon oxide film 51 are removed by the CMP method to form the plugs 41. The plug 41 is electrically connected to the wiring 39.

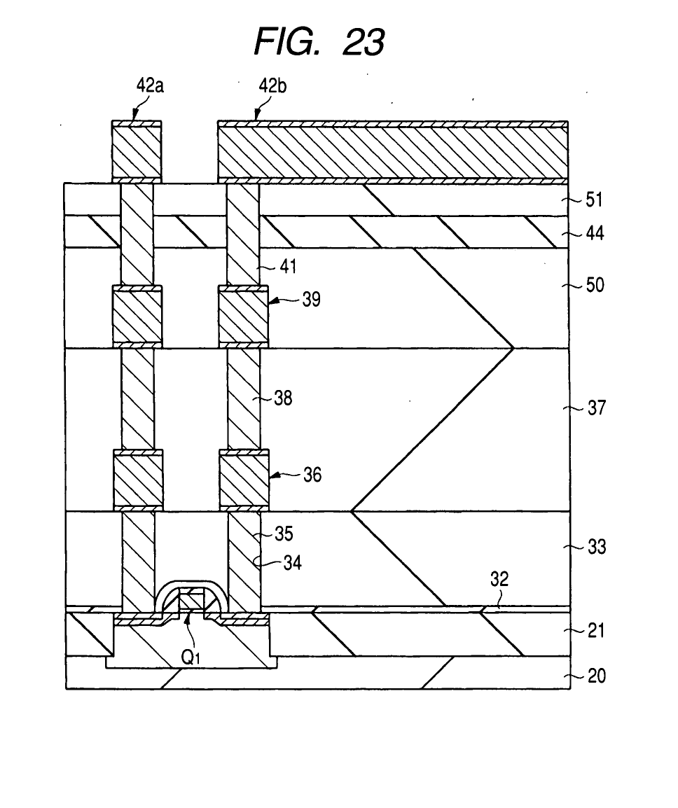

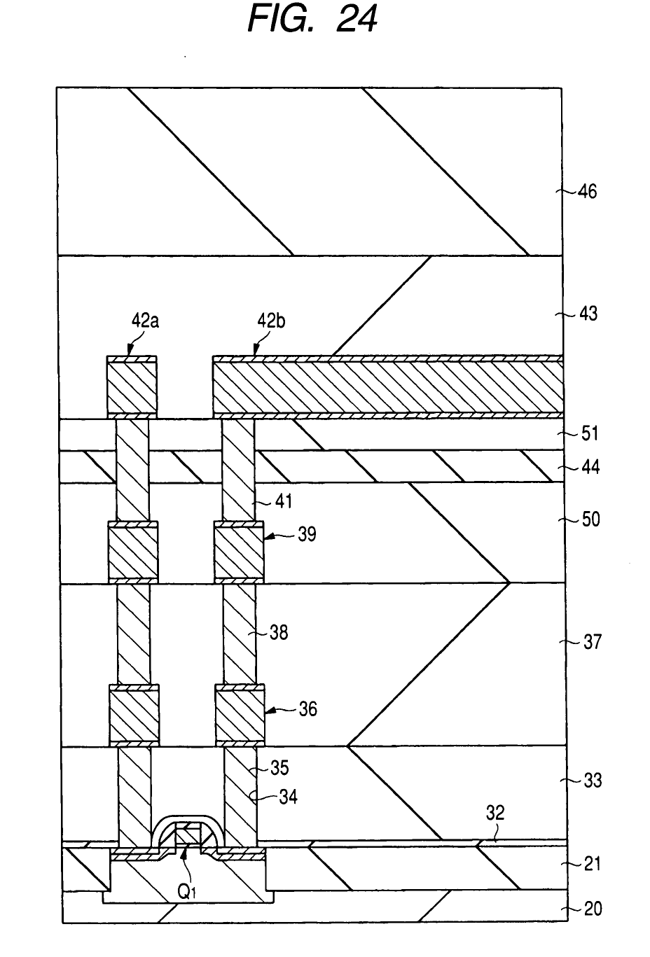

Then, as shown in FIG. 23, the titanium/titanium nitride film, the aluminum film, and the titanium/titanium nitride film are formed on the silicon oxide film 51 with the plugs 41 formed therein. These laminated films can be formed using, for example, the sputtering method. The laminated films are patterned using the photolithography technique and the etching technique to form the wirings 42a and 42b constituting the uppermost wiring layer.

Subsequently, as shown in FIG. 24, the silicon oxide film 43 is formed on the silicon oxide film 51 including the wirings 42a and 42b. The silicon oxide film 43 is the interlayer insulating film, and can be formed using, for example, the CVD method. The silicon nitride film 46 is formed on the silicon oxide film 43. The silicon nitride film 46 is a film serving as the surface protective film, and can be formed using, for example, the CVD method.

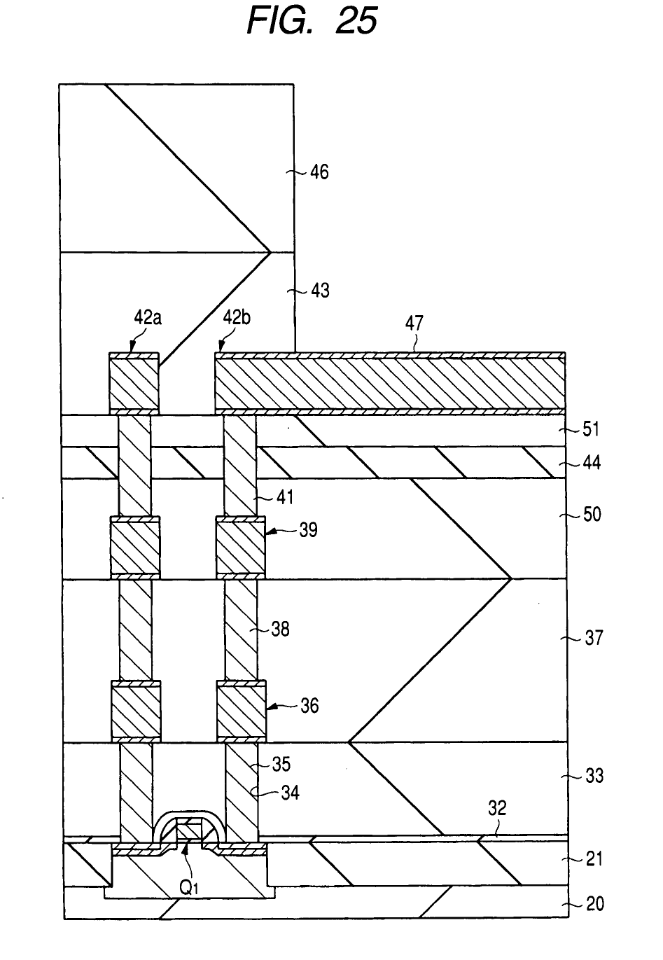

As shown in FIG. 25, an opening penetrating the silicon oxide film 43 and the silicon nitride film 46 is formed using the photolithography technique and the etching technique. At this time, a part of the wiring 42b is exposed at the bottom of the opening to form the bonding pads 47. In this way, the semiconductor device of the second embodiment can be formed.

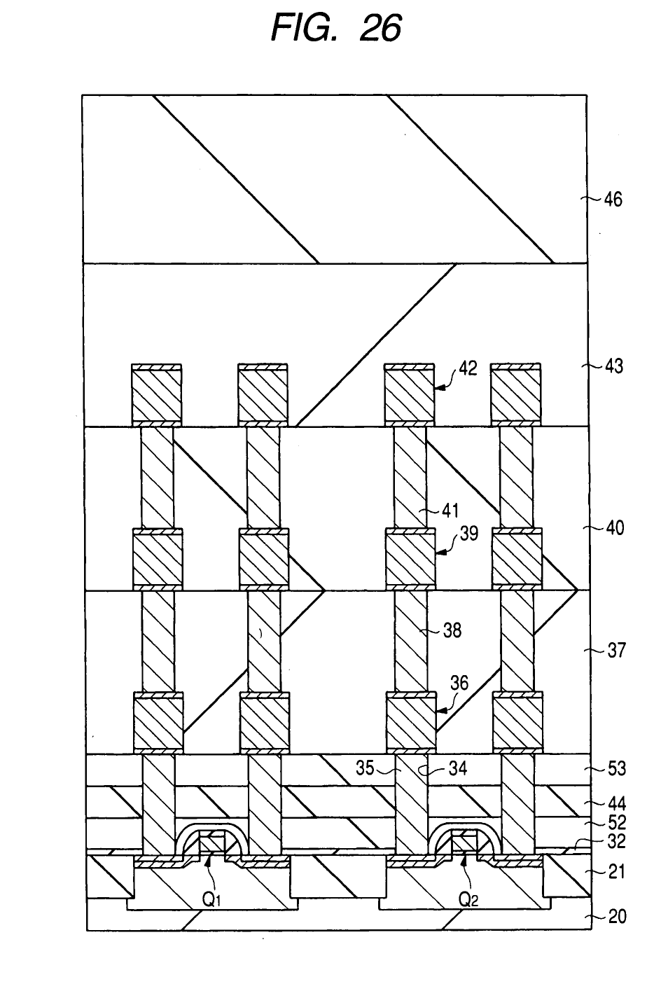

Although in the second preferred embodiment, as shown in FIG. 19, the colored thin film 44 is formed in the interlayer insulating film positioned between the wiring 39 constituting the second wiring layer and the wiring 42 constituting the uppermost wiring layer, for example, the colored thin film 44 may be formed in the interlayer insulating film between the wiring 36 constituting the first wiring layer and the wiring 39 constituting the second wiring layer to obtain the same effect. Furthermore, as shown in FIG. 26, the colored thin film 44 may be formed in the interlayer insulating film between the semiconductor substrate 20 over which the n-channel type MISFETQ1 and the p-channel type MISFETQ2 are formed and the wiring 36 constituting the first wiring layer to obtain the same effect. In FIG. 26, the silicon oxide film 52 is formed over the semiconductor substrate 20, and the colored thin film 44 is formed on the silicon oxide film 52. And, the silicon oxide film 53 is formed on the colored thin film 44, and the wiring 36 constituting the first wiring layer is formed on the silicon oxide film 53. In this case, the colored thin film 44 is formed under the lowermost wiring layer, thus making the removal of the film 44 more difficult.

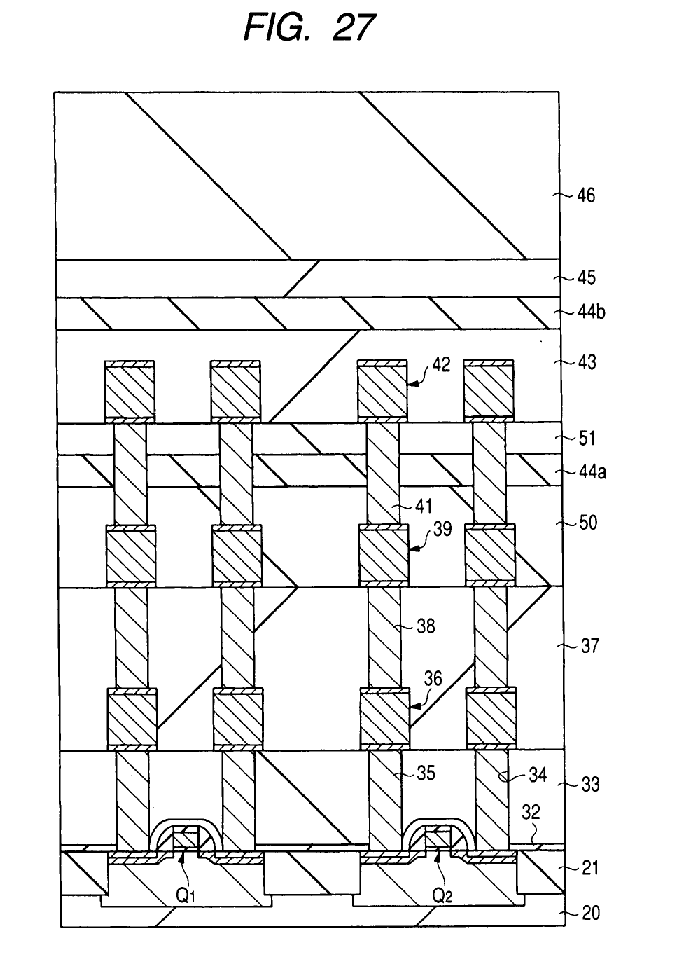

As shown in FIG. 27, a plurality of colored thin films may be provided in the interlayer insulating film or films. Referring to FIG. 27, the silicon oxide film 50 is formed on the wirings 39 constituting the second wiring layer, and the colored thin film 44a is formed on the silicon oxide film 50. The silicon oxide film 51 is formed on the colored thin film 44a, and the wirings 42 constituting the uppermost wiring layer are formed on the silicon oxide film 51. The silicon oxide film 43 is formed on the wirings 42, and the colored thin film 44b is formed on the silicon oxide film 43. The silicon oxide film 45 is formed on the colored thin film 44b. Thus, the colored thin film 44a is formed between the second wiring layer and the uppermost wiring layer, while the colored thin film 44b is formed between the uppermost wiring layer and the silicon nitride film 46, so that the security of the semiconductor device can be further improved. For example, the formation of the plural colored thin films can make the wiring patterns formed under the colored thin films more invisible, while enhancing the resistance to the attack using the laser light. The removal of the plural colored thin films involves complicated processes, which can enhance the resistance to the physical attack.

When the only one colored thin film does not have enough light blocking effect, the plural colored thin films are provided between the wiring layers, thereby ensuring the light blocking effect. That is, when the only one colored thin film does not have enough thickness to ensure the light blocking effect, the colored thin films may be formed in or at a plurality of interlayer insulating films so as to assure the light blocking effect.

Note that in FIG. 27, an example is described in which the colored thin films 44a and 44b are provided between the second wiring layer and the uppermost wiring layer, and between the uppermost wiring layer and the surface protective layer. However, the invention is not limited thereto, and the colored thin films may be formed, for example, between the first wiring layer and the second wiring layer, and between the second wiring layer and the uppermost wiring layer. Furthermore, three or more colored thin films may be formed.

### Third Preferred Embodiment

Although in the first and second embodiments, the colored thin film formed in the interlayer insulating film has been described, in a third preferred embodiment, a colored thin film formed in the same layer as the wiring layer will be described below as one example.

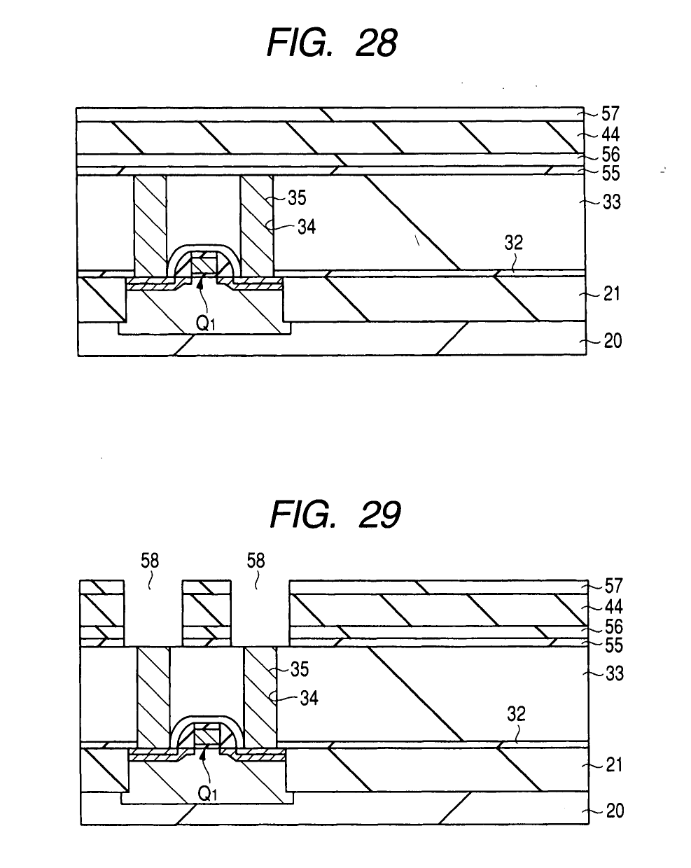

Now, a method of manufacturing a semiconductor device according to the third embodiment will be described. First, the steps of FIGS. 6 and 7 in the third embodiment are the same as those in the first embodiment. Subsequently, as shown in FIG. 28, a silicon nitride film 55, a silicon oxide film 56, the colored thin film 44, and a silicon oxide film 57 are laminated in that order over the silicon oxide film 33 having the plugs 35 formed therein. The silicon nitride film 55 serves as a barrier insulating film for preventing diffusion of copper atoms of a copper wiring, which are to be formed in the following step, into the semiconductor substrate 20. The silicon nitride film 55, the silicon oxide film 56, and the silicon oxide film 57 can be formed using, for example, the CVD method.

The colored thin film 44 is made of, for example, the silicon oxide film containing the cobalt oxide, and can be formed by, for example, the method as described in the first embodiment. For example, a solution into which silica is dissolved is prepared. The cobalt oxide is mixed into the solution with the silica dissolved thereto. Thereafter, the solution containing the cobalt oxide and the silica is applied to the silicon oxide film 56 (over the semiconductor substrate 20). Then, heat treatment is applied to the semiconductor substrate 20. This can form the colored thin film 44 composed of the silicon oxide film (SOG film) containing the cobalt oxide. The thickness of the colored thin film 44 is 100 nm or more and 2 μm or less.

Then, as shown in FIG. 29, wiring grooves 58 are formed to penetrate the silicon oxide film 57, the colored thin film 44, the silicon oxide film 56, and the silicon nitride film 55, using the photolithography technique and the etching technique. The plug 35 is exposed at the bottom of the wiring groove 58.

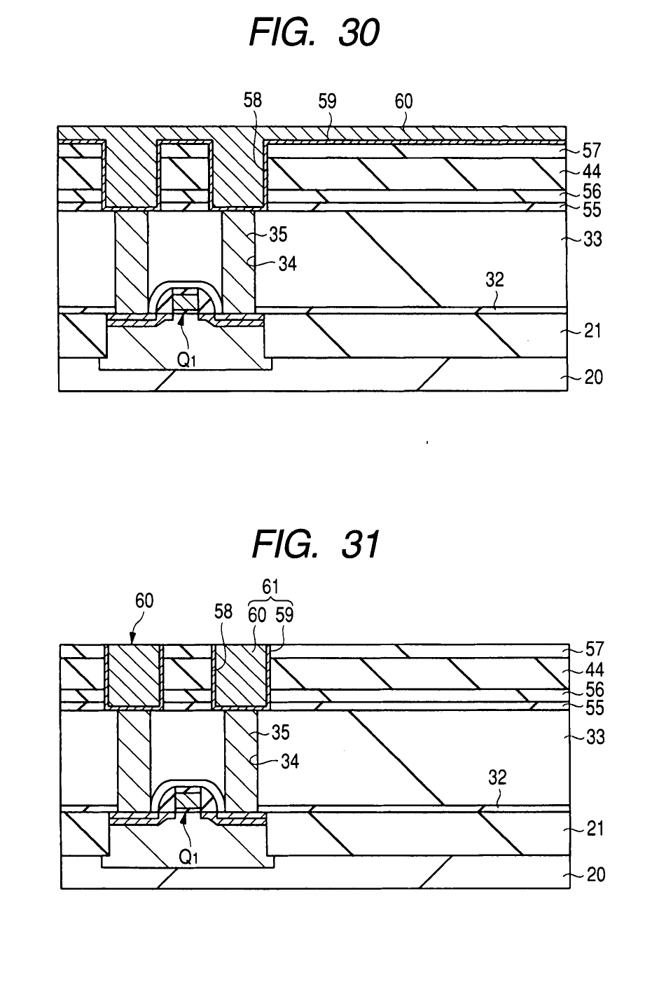

Subsequently, as shown in FIG. 30, a titanium/titanium nitride film 59 and a copper film 60 are formed on the silicon oxide film 57 including the wiring grooves 58. The titanium/titanium nitride film 59 can be formed using, for example, the sputtering, and the copper film 60 can be formed using, for example, a plating method.

Then, as shown in FIG. 31, the unnecessary titanium/titanium nitride film 59 and the unnecessary copper film 60 formed on the silicon oxide film 57 are removed using, for example, the CMP method to form an embedded wiring 61 in the wiring groove 58. At this time, the colored thin film 44 can be formed in the same layer as the embedded wiring 61. In other words, the colored thin film 44 is formed in the same interlayer insulating film in which the embedded wiring 16 is formed. In this case, the colored thin film 44 can make it difficult to view the structure under the thin film, thereby improving the security of the semiconductor device. Since the embedded wiring 61 is formed in the same layer as the colored thin film 44, the embedded wiring 61 may be damaged when removing the colored thin film 44. This can make it difficult to analyze the semiconductor device. That is, the formation of the colored thin film 44 in the same layer as the embedded wiring 16 can improve the resistance of the semiconductor device to the physical attack.

As shown in FIG. 31, the colored thin film 44 is in contact with the embedded wiring 61, and hence needs to be formed of an insulating material. As an example, the silicon oxide film containing the cobalt oxide can be used as mentioned above.

In the following steps, the wiring layer is formed using a single damascene method for forming embedded wirings, or a dual damascene method for forming embedded wirings and plugs at the same time, and these steps in the third embodiment will be omitted.

Although in the third embodiment, the colored thin film 44 formed in the same layer as the embedded wiring 61 constituting the first wiring layer is described as one example, the invention is not limited thereto. The colored thin film may be formed in the same layer as the second wiring layer, or in the same layer as the uppermost wiring layer.

It should be noted that although in the first and second embodiments, the wiring using the aluminum film has been described, a copper wiring can be applied to the invention. For example, when forming the copper wiring, which is embedded, the colored thin films may be used in the interlayer insulating film or films formed between a plurality of embedded wiring layers. Furthermore, although in the third embodiment, the copper wiring has been explained as an example, the embedded wiring may be formed of the aluminum film and the colored thin film may be formed in the same layer as the embedded wiring.

### Fourth Preferred Embodiment

In the first to third embodiments, the use of the colored thin film as one example has been explained. In a fourth embodiment, an example will be explained in which a laminated structure of films having different refractive indexes is used to block laser light in a specific wavelength region.

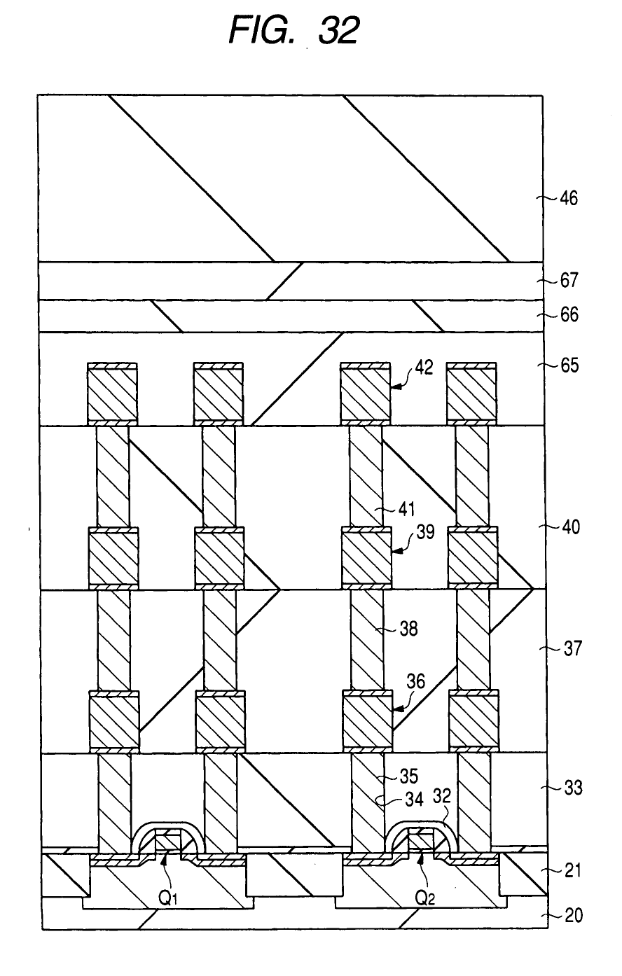

FIG. 32 is a sectional view showing a section of a semiconductor device according to the fourth embodiment. FIG. 32 is subsequently the same as FIG. 5 except for the following structure, which will only be described below. FIG. 32 differs from FIG. 5 in that a laminated film for blocking the laser light in the specific wavelength region is formed between the wiring 42 constituting the uppermost wiring layer and the silicon nitride film 46 serving as the surface protective film. In other words, a silicon oxide film 65, a silicon carbide film 66, and a silicon oxide film 67 are formed over the wirings 42. Since the silicon oxide films 65 and 67 differ from the silicon carbide film 66 in refractive index, the thickness of each of these films can be adjusted to block the laser light in the specific wavelength region. For example, setting the thicknesses of the silicon oxide films 65 and 67 and the silicon carbide film 66 to respective desired values can exhibit a function of attenuating the laser light having a wavelength of 532 nm. The specific wavelength of the laser light is not limited thereto, and the laminated film may have the function of attenuating the laser light having a wavelength of, for example, 266 nm, 355 nm, 1064 nm, or the like. That is, the laminated film may have the attenuation function of the laser light, such as Nd:YAG laser, which is generally used industrially.

In this way, the formation of such a laminated film composed of the films having the different refractive indexes can improve the resistance to the attack using the laser light as well as the security of the semiconductor device. Since the laminated film composed of the films having the different refractive indexes is provided under the surface protective film, it is difficult to remove the laminated film, thereby improving the resistance of the semiconductor device to the physical attack.

Although in the fourth embodiment, the laminated film composed of the films having the different refractive indexes is formed between the uppermost wiring layer (wiring 42) and the surface protective film (silicon nitride film 46) as one example, the invention is not limited thereto. For example, the laminated film composed of the films having the different refractive indexes may be formed between the second wiring layer (wiring 39) and the uppermost wiring layer (wiring 42) to obtain the same effect.

Furthermore, the cobalt oxide is contained in any one of the silicon oxide films 65 and 67 to form the colored thin film, which provides the effect of blocking the visible light. That is, the use of a difference in refractive index between the colored thin film and the silicon carbide film 66 can attenuate the laser light in the specific wavelength region. In addition, the colored thin film can attenuate the visible light.

Although in the fourth embodiment, the laminated film composed of the films having the different refractive indexes is formed of the silicon oxide film and the silicon carbide film, the invention is not limited thereto. Any films having the different refractive indexes can be selected, and the thicknesses of those films can be adjusted to block the laser light in the specific wavelength region.

The semiconductor device of the fourth embodiment is constructed as mentioned above, and a method of manufacturing the same will be described below with reference to the accompanying drawing.

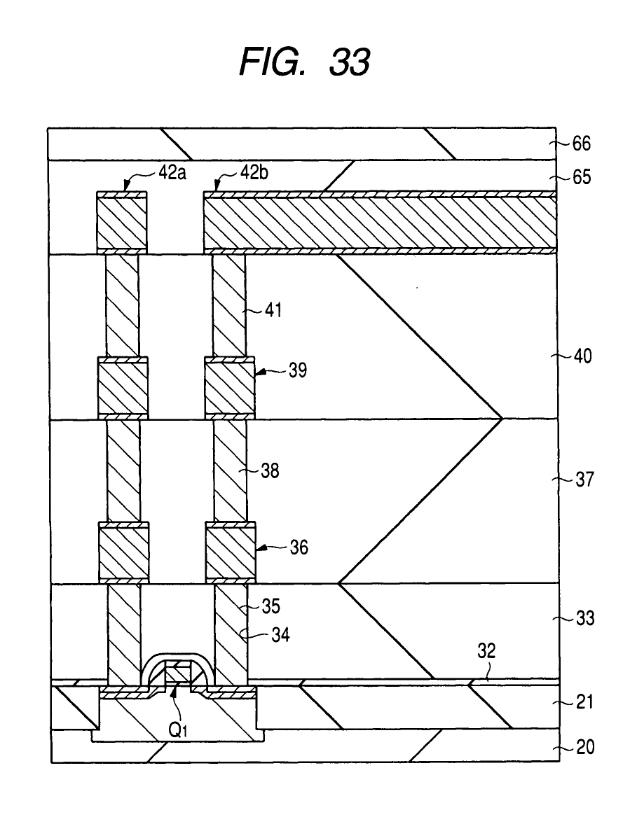

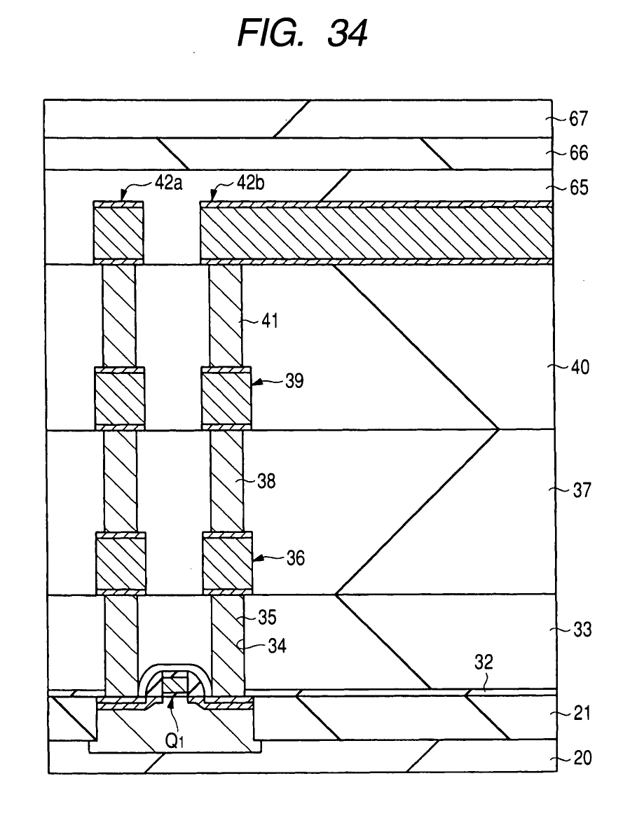

The steps of FIGS. 6 to 12 in the fourth embodiment are the same as those in the first embodiment. Subsequently, as shown in FIG. 33, the thin film for attenuating the light in the specific wavelength region is formed. More specifically, the silicon oxide film 65 is formed over the silicon oxide film 40 including the wirings 42a and 42b. The silicon carbide film 66 is formed on the silicon oxide film 65. The silicon oxide film 65 and the silicon carbide film 66 can be formed using, for example, the CVD method. Then, as shown in FIG. 34, the silicon oxide film 67 is formed on the silicon carbide film 66. The silicon oxide film 37 is also formed using, for example, the CVD method.

In this way, the thin film for attenuating the light in the specific wavelength region can be formed. That is, the laminated film composed of the silicon oxide film 65, the silicon carbide film 66, and the silicon oxide film 67, which have the different refractive indexes, can be formed. At this time, these films are formed such that the thickness of each of the films laminated can be set to the desired value, and hence have the function of attenuating the laser light in the specific wavelength region.

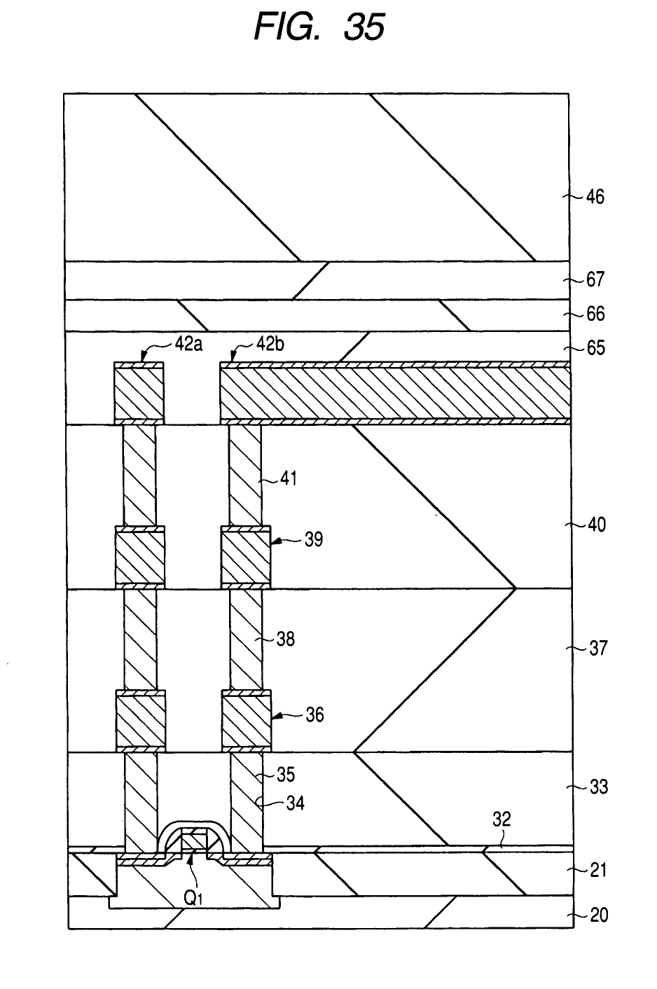

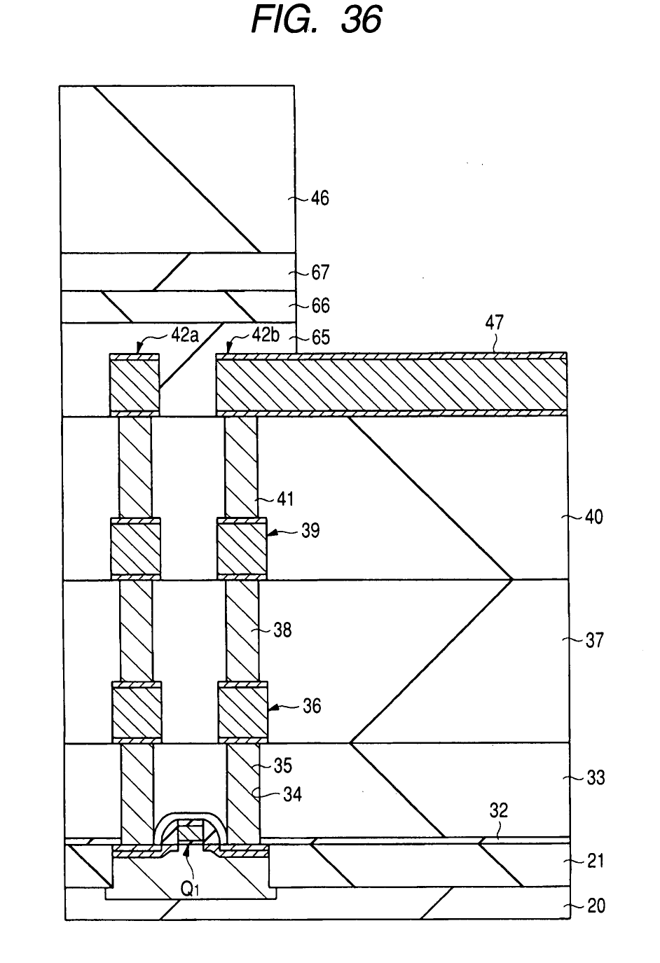

Then, as shown in FIG. 35, the silicon nitride film 46 is formed on the silicon oxide film 67. The silicon nitride film 46 serves as the surface protective film, and can be formed using, for example, the CVD method.

Then, as shown in FIG. 36, an opening penetrating the silicon oxide film 65, the silicon carbide film 66, the silicon oxide film 67, and the silicon nitride film 46 is formed using the photolithography technique and the etching technique. At this time, a part of the wiring 42b is exposed at the bottom of the opening to form the bonding pad 47. In this way, the semiconductor device of the fourth embodiment can be formed.

While the invention proposed by the inventors has been described and illustrated in detail based on the embodiments, it will be apparent to those skilled in the art that the invention is not limited thereto, and that various modification can be made to the embodiments without departing from the spirit and scope of the invention.

Combination of the techniques shown in the first to fourth embodiments with the known technique, for example, the active shield technique, or the dummy wiring technique can further improve the security of the semiconductor device.

The invention can be applied widely to the semiconductor manufacturing industry for manufacturing semiconductor devices, such as the IC card.

What is claimed is:

1. A semiconductor device comprising:
(a) an uppermost wiring layer formed over a semiconductor substrate;
(b) an interlayer insulating film formed over the uppermost wiring layer; and
(c) a surface protective film formed over the interlayer insulating film,
wherein a colored thin film for attenuating visible light and laser light in a specific wavelength region is formed in or at the interlayer insulating film.

2. The semiconductor device according to claim 1, wherein the colored thin film is an insulating film.

3. The semiconductor device according to claim 1, wherein the colored thin film is a conductive film.

4. The semiconductor device according to claim 2, wherein the colored thin film has a thickness of 100 nm or more and 2 μm or less.

5. The semiconductor device according to claim 2, wherein the colored thin film is formed of a silicon oxide film containing a metal oxide.

6. The semiconductor device according to claim 5, wherein the silicon oxide film is a SOG (Spin On Glass) film.

7. The semiconductor device according to claim 6, wherein the metal oxide is cobalt oxide.

8. The semiconductor device according to claim 3, wherein the colored thin film is formed of a graphite film.

9. The semiconductor device according to claim 8, wherein the graphite film has a thickness of 30 nm or more and 50 nm or less.

10. The semiconductor device according to claim 1, wherein the colored thin film is adapted to attenuate the laser light having a wavelength of 500 nm or more and 600 nm or less.

11. A semiconductor device comprising:
(a) a first wiring layer formed over a semiconductor substrate;
(b) an interlayer insulating film formed over the first wiring layer; and
(c) a second wiring layer formed over the interlayer insulating film,
wherein a colored thin film for attenuating visible light and laser light in a specific wavelength region is formed in or at the interlayer insulating film.

12. A semiconductor device comprising:
(a) a MISFET (metal-insulator-semiconductor field-effect transistor) formed over a semiconductor substrate;
(b) an interlayer insulating film formed over the MISFET; and
(c) a wiring layer formed over the interlayer insulating film,
wherein a colored thin film for attenuating visible light and laser light in a specific wavelength region is formed in or at the interlayer insulating film.

13. A semiconductor device comprising:
(a) an interlayer insulating film formed over a semiconductor substrate; and
(b) an embedded wire formed to be embedded into the interlayer insulating film,
wherein a colored thin film for attenuating visible light and laser light in a specific wavelength region is formed in or at the interlayer insulating film.

14. A semiconductor device comprising:
(a) a first interlayer insulating film formed over a semiconductor substrate;
(b) a wiring formed over the first interlayer insulating film; and
(c) a second interlayer insulating film formed over the wiring,
wherein a colored thin film for attenuating visible light and laser light in a specific wavelength region is formed in or at each of the first and second interlayer insulating films.

15. A semiconductor device comprising:
(a) an uppermost wiring layer formed over a semiconductor substrate;
(b) an interlayer insulating film formed over the uppermost wiring layer; and
(c) a surface protective film formed over the interlayer insulating film,
wherein a thin film for attenuating light in a specific wavelength region is formed in or at the interlayer insulating film.

16. The semiconductor device according to claim 15, wherein the thin film is formed of a plurality of films having different refractive indexes.

17. The semiconductor device according to claim 16, wherein the thin film is formed of a laminated film including a silicon oxide film and a silicon carbide film.

18. A method of manufacturing a semiconductor device, comprising the steps of:
(a) forming a wiring layer over a semiconductor substrate;
(b) forming an interlayer insulating film over the wiring layer; and
(c) forming a surface protective film over the interlayer insulating film,
wherein the (b) step comprises the step of:
(d) forming a colored thin film for attenuating visible light and laser light in a specific wavelength region.

19. The method according to claim 18, wherein the (d) step comprises the sub-steps of:
(d1) mixing a metal oxide into a solution containing silica;
(d2) applying to the semiconductor substrate the solution into which the metal oxide is mixed; and
(d3) forming a silicon oxide film containing the metal oxide by applying heat treatment to the semiconductor substrate to evaporate solvent in the solution.

20. The method according to claim 19, wherein the metal oxide is cobalt oxide.

21. The method according to claim 18, wherein the colored thin film is a graphite film formed by a plasma CVD (Chemical Vapor Deposition) method.

22. A method of manufacturing a semiconductor device, comprising the steps of:
(a) forming a first wiring layer over a semiconductor substrate;
(b) forming an interlayer insulating film over the first wiring layer; and
(c) forming a second wiring layer over the interlayer insulating film,
wherein the (b) step comprises the step of forming a colored thin film for attenuating visible light and laser light in a specific wavelength region.

23. A method of manufacturing a semiconductor device, comprising the steps of:
(a) forming a wiring layer over a semiconductor substrate;
(b) forming an interlayer insulating film over the wiring layer; and
(c) forming a surface protective film over the interlayer insulating film,
wherein the (b) step comprises the step of:
(d) forming a thin film for attenuating light in a specific wavelength region.

24. The method according to claim 23, wherein the (d) step involves forming a laminated film including films with different refractive indexes.

25. The method according to claim 24, wherein the (d) comprises the sub-steps of:
(d1) forming a silicon oxide film; and
(d2) forming a silicon carbide film whose refractive index is different from that of the silicon oxide film, over the silicon oxide film.
